(19) United States
(12) Patent Application Publication
(10) Pub. No.: US 2023/0386759 A1
(43) Pub. Date: Nov. 30, 2023

(54) METHODS OF VAPOR DEPOSITION OF METAL HALIDES

(71) Applicants: President and Fellows of Harvard College, Cambridge, MA (US); Trustees of Tufts College, Medford, MA (US)

(72) Inventors: Eliza Kate SPEAR, Cambridge, MA (US); Luke M. DAVIS, Medford, MA (US); Roy G. GORDON, Cambridge, MA (US)

(21) Appl. No.: 18/204,342

(22) Filed: May 31, 2023

Related U.S. Application Data
(60) Provisional application No. 63/347,325, filed on May 31, 2022.

(51) Int. Cl. H01G 9/20; H10K 30/10; C01G 3/04; C23C 16/455; C23C 16/30

(52) U.S. Cl. CPC H01G 9/2009; H01G 9/2036; H10K 30/10; C01G 3/04; C23C 16/45527; C23C 16/30; C01P 2004/03; C01P 2002/72; C01P 2002/85

(57) ABSTRACT

This disclosure presents methods for vapor deposition of metal halides involving exposure of substrates to vapors of organometallic copper complexes with halosilane vapors. The methods described herein are advantageous for the production of transparent hole conducting layers, e.g., for perovskite solar cells.

### BACKGROUND OF THE INVENTION

Transparent p- and n-type semiconductors are required for a variety of optoelectronic applications such as transparent electronics, photovoltaics (PVs), flat panel displays, light emitting diodes (LEDs), touchscreens, liquid-crystal displays (LCDs), and smart windows. Compared to their n-type counterparts, transparent p-type semiconductors are rare and have relatively low performance. Development of optically transparent p-type semiconductors with improved performance would benefit a variety of optoelectronic devices including fully transparent thin film transistors (TFTs), and semitransparent PVs and LEDs. Of especially high interest are transparent p-type semiconductors compatible with halide perovskite light absorbers or emitters, for PVs and LEDs respectively.

The cuprous halides (CuX, X═Cl, Br, I) are optically transparent p-type semiconductors. The band gaps of CuCl, CuBr, and CuI are 3.4, 2.9, and 3.1 eV, respectively. Polycrystalline CuBr films have resistivities of ˜10⁻¹ Ohm·cm, hole concentrations of ˜10¹⁷ cm⁻³, and hole mobilities of ˜0.1-3 cm²V⁻¹s⁻¹. CuI is of particular interest owing to its low resistivity (˜10⁻² Ohm·cm), high hole concentrations (˜10¹⁹ cm⁻³), and high hole mobility (˜1-10 cm²V⁻¹s⁻¹). All materials can have optical transparency of 80% or better below their bandgap as polycrystalline films.

Due to their promising properties, CuX have been utilized in a wide variety of optoelectronic devices. Vacuum evaporated CuCl was used as a buffer layer in CdTe PVs; solution deposited CuBr has been used in p-channel thin film transistors and as a hole transport material in organic PVs; and CuI, deposited via solution methods or iodination of Cu, has been used as the p-type layer in heterojunction diodes with ZnO, Agl, and Ga₂O₃, and as a hole-selective contact in CdTe, GaAs, dye-sensitized, and perovskite PVs.

To enable their commercial-scale use in various optoelectronic devices, scalable techniques capable of depositing device-quality thin films of CuX are desirable.

### SUMMARY OF THE INVENTION

In one aspect, the invention provides a method of producing a layer of a copper(I) halide. The method includes a) providing a substrate and b) exposing the substrate to a vapor of halosilane and a vapor of a copper complex. The copper complex and halosilane react to produce a layer of copper(I) halide on the substrate.

In some embodiments, the halosilane is a trialkylhalosilane. In some embodiments, the halosilane is Me₃Sil. In some embodiments, the copper(I) halide is cuprous iodide. In some embodiments, the copper complex includes a hexafluoroacetylacetonato ligand. In some embodiments, the copper complex includes a vinyltrimethylsilane (vtms) ligand. In some embodiments, the copper complex is Cu(hfac)(L), where L is a neutral ligand. In some embodiments, L is a phosphine, an alkene (e.g., vtms), an aromatic compound, or an alkyne (e.g., 2-butyne, bis(trimethylsilyl)acetylene, 2-methyl-1-hexen-3-yne or hex-3-yn-1-ene). In some embodiments, the copper complex is Cu(hfac)(vtms) (i.e., vinyltrimethylsilane (hexafluoroacetylacetonato) copper(I)). In some embodiments, the copper complex is Cu(hfac)(vtms) and the halosilane is Me₃Sil.

In some embodiments, the substrate is a current collector of a solar cell or a photovoltaic medium of a solar cell. In some embodiments, the solar cell is a perovskite solar cell. In some embodiments, the perovskite includes methylammonium tin trishalide, methylammonium lead trishalide, cesium tin trishalide, cesium lead trishalide, formamidinium tin trishalide, formamidinium lead trishalide, or a combination thereof. In some embodiments, the perovskite may include a mixture of Q counterions, a mixture of M metals (e.g., transition metals, e.g., Pb and Sn), and/or a mixture of X halides, e.g., (Q′ₐQ″_{b}Q″′_{c})M═_{d}M″ₑ(X′_{f}X″_{g}X″′ₕ)₃, where a=0 to 1, b=0 to 1, c=0 to 1 and (a+b+c)=1, where d=0 to 1, e=0 to 1, and (d+e)=1, and where f=0 to 1, g=0 to 1, h=0 to 1 and (f+g+h)=1, e.g., (MAₐFA_{b}Cs_{c})Pb_{d}Snₑ(Cl_{f}Br_{g}Iₕ)₃, where a=0 to 1, b=0 to 1, c=0 to 1 and (a+b+c)=1, where d=0 to 1, e=0 to 1, and (d+e)=1, and where f=0 to 1, g=0 to 1, h=0 to 1 and (f+g+h)=1. In some embodiments, the substrate is SiO₂, SiNₓ, Pt, ITO, FTO, quartz, carbon (e.g., graphite, graphene, graphene oxide, vitreous carbon, etc., e.g., a carbon planchet), a flexible polymer film (e.g., a polyimide (e.g., poly-oxydiphenylene-pyromellitimide (e.g., Kapton®)), polypropylene, cyclic olefin copolymer, polyethylene terephthalate, polyethylene, polyvinylchloride, polyetherimide, poly ether ketone, poly(methyl methacrylate), polydimethylsiloxane etc.), methylammonium lead trisiodide perovskite films, or single crystals of NaCl, KCl, or KBr.

In some embodiments, the substrate is a metal, a semiconductor, an optoelectronic material, a photovoltaic material, a dielectric, an interfacial layer, a sacrificial layer, a templating layer, or an adhesion layer.

In some embodiments, the substrate is first exposed to the halosilane vapor. In some embodiments, a pressure of the halosilane vapor is from 10 to 500 times that of a copper complex vapor. In some embodiments, a concentration of the halosilane vapor is from 10 to 500 times that of a copper complex vapor. In some embodiments, the method includes exposing the substrate to the halosilane and the copper complex at the same time or in a pulsed manner without purging between exposures followed by purging unreacted copper complex and halosilane to perform a cycle. In some embodiments, the method includes alternating exposure of the substrate to the halosilane and the copper complex separated by a purge to perform a cycle (e.g., ALD). In some embodiments, the method includes performing a plurality of cycles. In some embodiments, the plurality of cycles includes 10-50,000 cycles (e.g., 10-100, 50-500, 100-1000, 500-5000, 500-1500, 1,000-1,500, 1,000-2,000, 1,000-10,000, 1,500-3,000, 2,000-5,000, 2,500-5,000, 3,000-6,000, 5,000-10,000, 5,000-7,500, 6,000-9,000, 8,000-10,000, 7,500-15,000, 10,000-20,000, 15,000-30,000, 20,000-40,000, 25,000-50,000, 30,000-40,000, 40,000-e.g., about 100, 500, 1,000, 2,000, 3,000, 4,000, 5,000, 10,000, 20,000, 30,000, 40,000, or 50,000 cycles). In some embodiments, the copper halide is deposited in a continuous (e.g., without defects or pinholes) film on the substrate.

In another aspect, the invention provides a solar cell. The solar cell includes an electron injection layer, an electron collection layer, a perovskite absorbing layer disposed between the electron injection layer and electron collection layer, an n-type electron transport layer disposed between the electron collection layer and the perovskite absorbing layer, and a p-type hole transport layer disposed between the perovskite absorbing layer and the electron injection layer. The p-type hole transport layer includes a metal halide (e.g., produced by a method described herein, e.g., CuI) and the perovskite absorbing layer and the p-type hole transport layer are in physical contact.

In some embodiments, the metal halide is copper iodide.

In some embodiments, the perovskite absorbing layer has a ratio XRD peak areas of MX₂ to QMX₃ of less than 22%, where Q is a cationic counterion, e.g., an ammonium counterion, or a mixture of counterions, X is a halide or a combination of halides, and M is a metal or combination of metals. In some embodiments, the ratio of MX₂ to QMX₃ is less than 10%. In some embodiments, the ratio of MX₂ to QMX₃ is less than 5%. In some embodiments, the ratio of MX₂ to QMX₃ is less than 1%. In some embodiments, M=Pb and X=I. In some embodiments, Q is methylammonium (MA). In some embodiments, Q is a mixture of MA formamidinium (FA) and Cs. In some embodiments, X is a mixture of halides.

In some embodiments, the perovskite absorber layer has a ratio of XRD peak areas of a degradation product to a peak of the perovskite that corresponds to less than 22% degradation by XRD. In some embodiments, the perovskite absorber layer shows less than 10% degradation by XRD, e.g., less than 5%, less than 1%, e.g., no degradation by XRD.

In some embodiments, the electron injection layer is reflective. In some embodiments, the electron injection layer is transparent or semi-transparent. In some embodiments, the electron collection layer includes one or more of ITO, FTO, doped zinc oxide, In or Sn-doped cadmium oxide, Zn₂SnO₄, ZnSnO₃, Zn₂In₂O₅, Zn₃In₂O₆, Cd₂SnO₄, CdSnO₃, CdIn₂O₄, MgIn₂O₄, GaInO₃, Sn or Ge-doped gallium oxide, Y-doped CdSb₂O₆, Zn₂In₂O₅—In₄Sn₃O₁₂, CdIn₂O₄—Cd₂SnO₄, or ZnO—CdO—In₂O₃—SnO₂.

In some embodiments, the perovskite may include a mixture of Q counterions, a mixture of M metals (e.g., transition metals, e.g., Pb and Sn), and/or a mixture of X halides, e.g., (Q′ₐQ″_{b}Q″′_{c})M═_{d}M″ₑ(X′_{f}X″_{g}X″′ₕ)₃, where a=0 to 1, b=0 to 1, c=0 to 1 and (a+b+c)=1, where d=0 to 1, e=0 to 1, and (d+e)=1, and where f=0 to 1, g=0 to 1, h=0 to 1 and (f+g+h)=1, e.g., (MAₐFA_{b}Cs_{c})Pb_{d}Snₑ(Cl_{f}Br_{g}Iₕ)₃, where a=0 to 1, b=0 to 1, c=0 to 1 and (a+b+c)=1, where d=0 to 1, e=0 to 1, and (d+e)=1, and where f=0 to 1, g=0 to 1, h=0 to 1 and (f+g+h)=1. In some embodiments, the perovskite includes methylammonium tin trishalide, methylammonium lead trishalide, cesium tin trishalide, cesium lead trishalide, formamidinium tin trishalide, formamidinium lead trishalide, or a combination thereof. In some embodiments, the perovskite absorbing layer includes MAPbBr₃, MAPbI₃, FAPbI₃, MAPb₁₋ₓSnₓI₃, or MASnI₃.

In some embodiments, the p-type hole transport layer is deposited on the perovskite absorbing layer by chemical vapor deposition. In some embodiments, the p-type hole transport layer is a continuous layer of the copper halide (e.g., without pinholes).

In another aspect, the invention provides a composition. The composition includes a substrate and a copper halide layer in physical contact with the substrate. The substrate material physically or chemically degrades at a temperature between 35° C. and 200° C. and/or is chemically reactive to hydrogen halides and/or copper complexes at or above room temperature.

In some embodiments, the copper halide layer is a CuI layer. In some embodiments, the substrate is a metal, a semiconductor, an optoelectronic material, a photovoltaic material, a dielectric, an interfacial layer, a sacrificial layer, a templating layer, or an adhesion layer. In some embodiments, the substrate includes carbon (e.g., vitreous carbon, graphite, graphene, graphene oxide, etc., e.g., a carbon planchet), a flexible polymer film (e.g., a polyimide, e.g., poly-oxydiphenylene-pyromellitimide (e.g., Kapton®) tape or film, or, e.g., a polypropylene, cyclic olefin copolymer, polyethylene terephthalate, polyethylene, polyvinylchloride, polyetherimide, poly ether ketone, poly(methyl methacrylate), or polydimethylsiloxane film), perovskite (e.g., methylammonium lead trisiodide) films. In some embodiments, the substrate is a photovoltaic material. In some embodiments, the substrate is a perovskite absorber layer.

In some embodiments, the substrate has a ratio of XRD peak areas of a degradation product to a peak of the substrate that corresponds to less than 22% degradation by XRD (e.g., relative to pristine substrate). In some embodiments, the substrate shows less than 10% degradation by XRD, e.g., less than 5%, less than 1% (e.g., no degradation by XRD), e.g., relative to pristine substrate.

In some embodiments, the composition includes one or more of ITO, FTO, doped zinc oxide, In or Sn-doped cadmium oxide, Zn₂SnO₄, ZnSnO₃, Zn₂In₂O₅, Zn₃In₂O₆, Cd₂SnO₄, CdSnO₃, CdIn₂O₄, MgIn₂O₄, GaInO₃, Sn or Ge-doped gallium oxide, Y-doped CdSb₂O₆, Zn₂In₂O₅—In₄Sn₃O₁₂, CdIn₂O₄—Cd₂SnO₄, or ZnO—CdO—In₂O₃—SnO₂.

In some embodiments, the perovskite may include a mixture of Q counterions, a mixture of M metals (e.g., transition metals, e.g., Pb and Sn), and/or a mixture of X halides, e.g., (Q′ₐQ″_{b}Q″′_{c})M═_{d}M″ₑ(X′_{f}X″_{g}X″′ₕ)₃, where a=0 to 1, b=0 to 1, c=0 to 1 and (a+b+c)=1, where d=0 to 1, e=0 to 1, and (d+e)=1, and where f=0 to 1, g=0 to 1, h=0 to 1 and (f+g+h)=1, e.g., (MAₐFA_{b}Cs_{c})Pb_{d}Snₑ(Cl_{f}Br_{g}Iₕ)₃, where a=0 to 1, b=0 to 1, c=0 to 1 and (a+b+c)=1, where d=0 to 1, e=0 to 1, and (d+e)=1, and where f=0 to 1, g=0 to 1, h=0 to 1 and (f+g+h)=1. In some embodiments, the substrate includes methylammonium tin trishalide, methylammonium lead trishalide, cesium tin trishalide, cesium lead trishalide, formamidinium tin trishalide, formamidinium lead trishalide, or a combination thereof. In some embodiments, the substrate includes MAPbBr₃, MAPbI₃, FAPbI₃, MAPb₁₋ₓSnₓI₃, or MASnI₃,

In some embodiments, the copper halide layer is deposited on the substrate by chemical vapor deposition (e.g., according to the methods described herein). In some embodiments, the copper halide layer is a continuous layer of the copper halide (e.g., without pinholes).

### DEFINITIONS

To facilitate the understanding of this invention, a number of terms are defined below. Terms defined herein have meanings as commonly understood by a person of ordinary skill in the areas relevant to the invention. Terms such as “a”, “an,” and “the” are not intended to refer to only a singular entity but include the general class of which a specific example may be used for illustration. The terminology herein is used to describe specific embodiments of the invention, but their usage does not limit the invention, except as outlined in the claims.

The term “about,” as used herein, refers to ±10% of a recited value.

By “halo” is meant fluoro, chloro, bromo, or iodo.

By “silane” is meant a compound having an Si atom with n=1-4 hydrocarbyl or aryl substituents by Si-C σ-bonds. When n<4, the remaining 1-3 substituents may be halo groups.

By “hydrocarbyl,” as used herein, is meant straight chain or branched saturated or unsaturated groups of carbons. Exemplary hydrocarbyl groups include alkyl (saturated), alkenyl (unsaturated with at least one carbon double bond and no carbon triple bonds), and alkynyl (unsaturated with at least one carbon triple bond). Alkyl groups are exemplified by n-, sec-, iso- and tert-butyl, neopentyl, nonyl, decyl, and the like, and may be optionally substituted with one or more, substituents. Hydrocarbyl groups of the invention may include 1 or more carbon atoms, e.g., greater than 2, e.g., 6-15, such as 8-12, or 4-36 in the main chain. Carbon atoms in the main chain may or may not be interrupted with one or more heteroatoms, e.g., O, S, or N.

By “aryl” is meant an aromatic cyclic group in which the ring atoms are all carbon. Exemplary aryl groups include phenyl, naphthyl, and anthracenyl. Aryl groups may be optionally substituted with one or more substituents.

By “alkyl” as used herein, is meant straight-chain or branched saturated groups of carbons. Alkyl groups are exemplified by n-, sec-, iso-, tert-butyl, neopentyl, nonyl, decyl, and the like, and may be optionally substituted with one or more substituents. Alkyl groups of the invention may include 1-6 carbon atoms.

Carbon atoms in the main chain may be interrupted with one or more heteroatoms, e.g., oxygen, sulfur, or nitrogen.

By “carbocyclyl” is meant a non-aromatic cyclic group in which the ring atoms are all carbon. Exemplary carbocyclyl groups include cyclopropyl, cyclobutyl, cyclopentyl, cyclohexyl, cycloheptyl, and cyclooctyl. Carbocyclyl groups may be optionally substituted with one or more substituents. A carbocyclyl group may or may not be saturated.

By “heterocyclyl” is meant a cyclic group in which the ring atoms include at least one carbon and at least one O, N, or S atom, provided that at least three ring atoms are present. Heterocyclyl groups may be optionally substituted with one or more substituents.

By “heteroaryl” is meant an aromatic cyclic group in which the ring atoms include at least one carbon and at least one O, N, or S atom, provided that at least three ring atoms are present. Exemplary heteroaryl groups include oxazolyl, isoxazolyl, tetrazolyl, pyridyl, thienyl, furyl, pyrrolyl, imidazolyl, pyrimidinyl, thiazolyl, indolyl, quinolinyl, isoquinolinyl, benzofuryl, benzothienyl, pyrazolyl, pyrazinyl, pyridazinyl, isothiazolyl, benzimidazolyl, benzothiazolyl, benzoxazolyl, oxadiazolyl, thiadiazolyl, and triazolyl. Heteroaryl groups may be optionally substituted with one or more substituents.

By “polyfluorocarbyl” is meant a straight chain or branched saturated or unsaturated groups of carbons where at least two hydrogens are replaced by fluorine. Exemplary hydrocarbyl groups include polyfluoroalkyl (saturated), polyfluoroalkenyl (unsaturated with at least one carbon double bond and no carbon triple bonds), and polyfluoroalkynyl (unsaturated with at least one carbon triple bond). Polyfluorocarbyl groups may be polyfluoroalkyl groups, e.g., perfluoroalkyl groups (i.e., wherein all hydrogens are replaced with fluorine). Polyfluoroalkyl groups may include a mixture of methylene (CH₂) and difluoromethylene (CF₂) units; for example, a methylene is connected to a heteroatom, a carboxy group or an aryl group, but the rest of the chain is fluorinated. Polyfluoroalkyl groups are exemplified by methyl, ethyl, n- or iso-propyl, n-, sec-, iso- and tert-butyl, neopentyl, nonyl, decyl, and the like, and may be optionally substituted with one or more, substituents. Polyfluorocarbyl groups of the invention may include 1 or more carbon atoms, e.g., greater than 2, e.g., 6-15, such as 8-12, or 4-36 in the main chain. Carbon atoms in the main chain may or may not be interrupted with one or more heteroatoms, e.g., O, S, or N.

Optional substituents include halo, optionally substituted C₃₋₁₀ carbocyclyl; optionally substituted C₁₋₉ heterocyclyl having one to four heteroatoms independently selected from O, N, and S; optionally substituted C₆₋₂₀ aryl; optionally substituted C₁₋₉ heteroaryl having one to four heteroatoms independently selected from O, N, and S; —CN; —N_{O}2; —ORₐ; —N(Ra)₂; —C(═O)Ra; —C(═O)ORₐ; —S(═O)₂Rₐ; —(═O)₂ORₐ; —P(═O)Rₐ₂; —O—P(═O)(ORₐ)₂, or —P(═O)(ORₐ)₂, or an ion thereof; where each Ra is independently H or optionally substituted C₁₋₉ hydrocarbyl (e.g., C₁₋₉ alkyl). Cyclic groups may also be substituted with optionally substituted C₁₋₉ hydrocarbyl (e.g., C₁₋₉ alkyl).

### BRIEF DESCRIPTION OF THE DRAWINGS

FIGS. 1(a)-1(k) shows scanning electron micrographs of CuI on (a) silicon dioxide, (b) silicon nitride, (c) quartz, (d) ITO, (e) FTO, (f) Pt, (g) NaCl(100), (h) KBr(100), (i) KCl(100), (j) Kapton® film, and (k) vitreous carbon planchet; each image width is 1.33 microns. All films were grown from TMSI-first open valve pulsed CVD reactions between Cu(hfac)(vtms) and TMSI at 50° C.; all CuI films shown were grown from 1000 cycles except the film on Kapton®, which was grown from 2000 cycles. Cross sections of films on Kapton® and vitreous carbon are not included due to difficulty in cleaving the samples.

FIGS. 2(a)-2(k) shows scanning electron micrographs of CuI grown from 1000 cycles of TMSI-first open valve pulsed CVD reaction between Cu(hfac)(vtms) and TMSI at 50° C. on (a) silicon dioxide, (b) silicon nitride, (c) quartz, (d) ITO, (e) FTO, (f) Pt, (g) NaCl(100), (h) KBr(100), (i) KCl(100), (j) Kapton® film, and (k) vitreous carbon planchet; each image width is 10 microns.

FIGS. 3(a)-3(k) shows X-ray diffractograms of CuI grown from 1000 cycles of TMSI-first open valve pulsed CVD reaction between Cu(hfac)(vtms) and TMSI at 50° C. on (a) silicon dioxide, (b) silicon nitride, (c) quartz, (d) ITO, (e) FTO, (f) Pt, (g) NaCl(100), (h) KBr(100), (i) KCl(100), (j) Kapton® film, and (k) vitreous carbon planchet. Asterisks indicate reflections associated with the substrate.

FIGS. 4(a)-4(c) show X-ray diffractograms plotted on a log scale of CuI grown from 1000 cycles of TMSI-first open valve pulsed CVD reaction between Cu(hfac)(vtms) and TMSI at 50° C. on: (a) NaCl(100); (b) KBr(100); and (c) KCl(100). Asterisks indicate reflections associated with the substrate.

FIGS. 5(a) and 5(b) show XPS depth profiles of CuI grown (a) on various substrates, with XPS etch times of 400 s and (b) on Pt, with XPS etch time of 880 s to probe deeper into the CuI film. In (a) iodine to copper ratios in CuI films as determined by X-ray photoelectron spectroscopy depth profiles (XPS data collected after every 80 s of Ar⁺ sputter etching; 400 s etch time) for CuI grown from open valve pulsed CVD reaction between Cu(hfac)(vtms) and TMSI on various substrates at 50° C. Note that these results are uncalibrated and therefore do not provide absolute quantification of elements. All films were grown in 1000 cycles except films on ITO, Kapton®, and carbon planchet, which were grown in 2000 cycles. The CuI film on Pt in (a) appears to have about the same Cu/I ratio as films on other substrates via XPS, indicating about 1:1 Cu:I in the film surface despite evidence of overall Cu enrichment in the film by RBS. The longer depth profile in (b), with 880 s total etch time, indicated that the film is more Cu-rich closer to the Pt substrate.

FIGS. 6(a)-6(b) show (a) UV-Vis transmittance spectrum of CuI film on quartz, and (b) photograph of CuI film on FTO/glass; both films were deposited from 1000 cycles of TMSI-first open valve pulsed CVD reaction between Cu(hfac)(vtms) and TMSI at 50° C.

FIG. 7 shows a summary of Hall effect measurement results for CuI films on quartz and NaCl(100) substrates, deposited from 1000 cycles of TMSI-first open valve pulsed CVD reaction between Cu(hfac)(vtms) and TMSI at 50° C. Contacts (10 nm Ti/200 nm Au) were deposited at the corners of each sample by electron beam evaporation through a shadow mask. Sample thicknesses are estimated to be ˜50-120 nm and ˜100-150 nm on NaCl(100), based on SEM cross sections of similar samples; ranges of thickness-dependent values are provided. Hall measurement results are reported for three measurement dates (0, 30, and 133 days); samples were stored in a nitrogen box between measurements.

FIGS. 8(a)-8(d) shows X-ray diffractograms and calculated PbI₂(001) to MAPbI₃(002/1̅1̅0) peak area ratios for MAPbI₃: (a) as-received; and after 500 cycles of TMSI-first open valve pulsed CVD at 50° C. with TMSI:Cu(hfac)(vtms) pressure ratio of (b) ˜10, (c) ˜40, and (d) ˜130. TMSI:Cu(hfac)(vtms) (labelled in the figure as “TMSI:Cu(h)(v)”) indicates the precursor dosing pressure ratio, and PbI₂:MAPI indicates the PbI₂(001):MAPbI₃(002/1̅1̅0) peak area ratio.

FIG. 9(a)-9(f) shows scanning electron micrographs of MAPbI₃ after 500 cycles of TMSI-first open valve pulsed CVD at 50° C. with TMSI:Cu(hfac)(vtms) pressure ratio ˜130 (PbI₂(001):MAPbI₃(002/1̅1̅0) peak area ratio ˜0.2) (a,b,c), and pressure ratio ˜40 (PbI₂(001):MAPbI₃(002/1̅1̅0) peak area ratio ˜0.4) (d,e,f). PbI₂ is not labeled in (c) and (e) because a distinct PbI₂ layer is not obvious via SEM cross section and the precise location of the PbI₂ is unknown.

FIG. 10 shows an example of a reactor diagram for a reactor capable of performing the methods described herein, and of producing compositions and devices such as those described herein.

FIGS. 11(a)-11(d) shows scanning electron micrographs of CuI grown from 1000 cycles of pulsed CVD reaction between Cu(hfac)(vtms) and TMSI on silicon dioxide at substrate temperatures of (a) 50° C., (b) 90° C., (c) 140° C., and (d) 200° C.; each image width is 5 microns.

FIGS. 12(a)-12(d) shows scanning electron micrographs of CuI grown from 1000 cycles of pulsed CVD reaction between Cu(hfac)(vtms) and TMSI on NaCl(100) at substrate temperatures of (a) 50° C., (b) 90° C., (c) 140° C., and (d) 200° C.; each image width is 5 microns.

FIG. 13 shows a proposed chemical reaction of CuI growth according to methods of the invention.

FIG. 14 is a representation of a perovskite solar cell such as may be prepared according to method described herein.

FIG. 15(a)-(c) shows scanning electron micrographs of a NaCl(100) substrates after 500 cycles of closed valve ALD deposition at 50° C.

FIG. 16 shows XRD of a NaCl(100) substrate after 500 cycles of closed valve ALD deposition at 50° C.

### DETAILED DESCRIPTION OF THE INVENTION

The invention provides a new chemical vapor deposition (CVD) technique utilizing an alternative iodine precursor and optoelectronic devices that are made possible by the new technique. A new ALD method is also described.

Previous CVD methods employed hydrogen halides (HX) as the halide source. However, HX can be damaging to vacuum equipment, and can also inflict damage upon certain substrates, such as substrates described herein. CuI stands out among the cuprous halides for its particularly promising electrical properties, but CVD of CuI using this method requires use of anhydrous hydrogen iodide. Anhydrous HI is difficult to source commercially and is difficult to store due to its facile, exergonic decomposition to H₂ and I₂.

In addition, due to purchasing and handling difficulties, HI may also be incompatible with perovskite absorber materials, which are particularly exciting substrates for device applications of CuI (e.g., in perovskite solar cells, smart windows, etc.). Hydrogen halide gases have been shown to undergo halide exchange with methylammonium lead trihalides at 120° C. Because the highest-performing halide perovskite PVs employ careful engineering of the balance of halides Cl, Br, and I in the light-absorbing perovskite layer to optimize their optoelectronic properties, these exchange reactions would lead to undesirable perovskite compositions and lower device quality.

Films are desirably continuous, pinhole-free, and have precisely controlled thickness and composition. The present deposition technique is capable of depositing such CuX films on a wide variety of substrates, with the specific selection depending upon the demands of a desired application. For example, TFTs require deposition of the semiconductor atop an insulator or gate dielectric. Deposition atop flexible substrates such as polymer films, e.g., using the methods described herein, allows use of these materials in transparent flexible electronics. For application as carrier-selective contacts in photovoltaic devices, different device configurations demand deposition atop various substrates. The CuX film may need to be deposited atop a current collecting layer (e.g., a metal, indium tin oxide (ITO), or fluorine-doped tin oxide (FTO)), a light-absorbing material (e.g., CdTe, GaAs, organic photovoltaic, or metal halide perovskite), or, in the case of multijunction solar cells, a recombination layer such as ITO. Some applications may also demand conformal coatings on non-planar substrates, such as incorporation into textured solar cells.

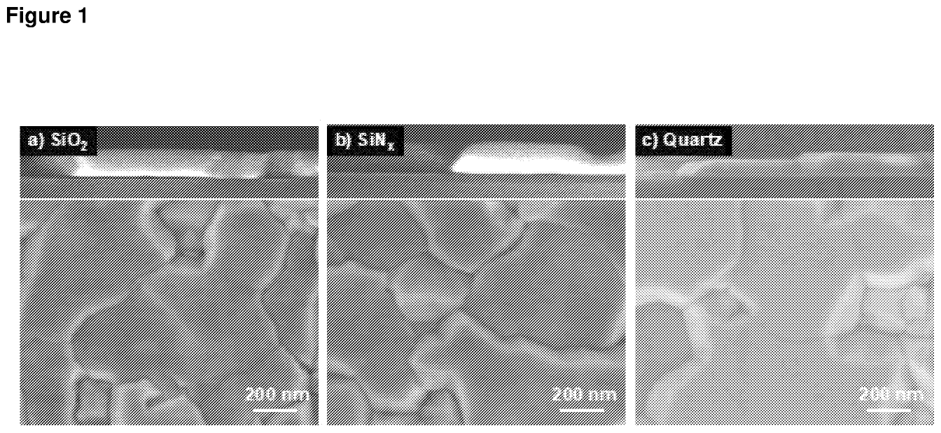

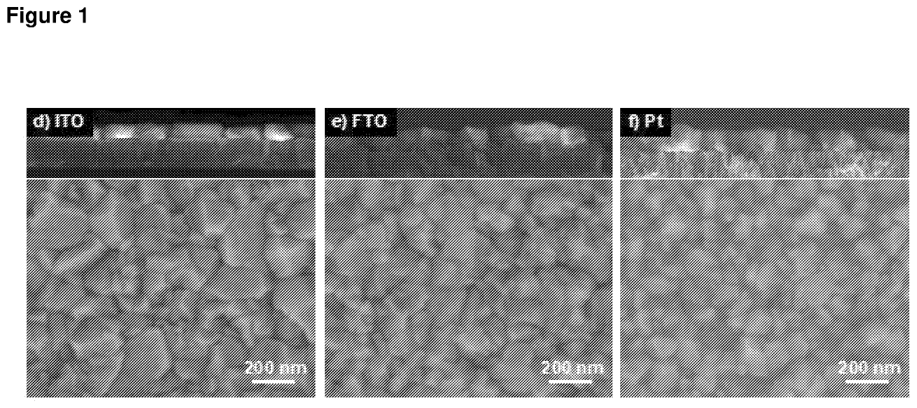

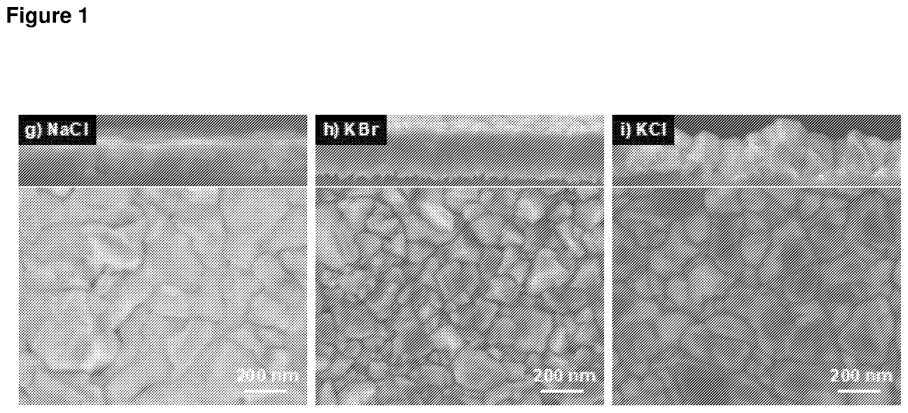

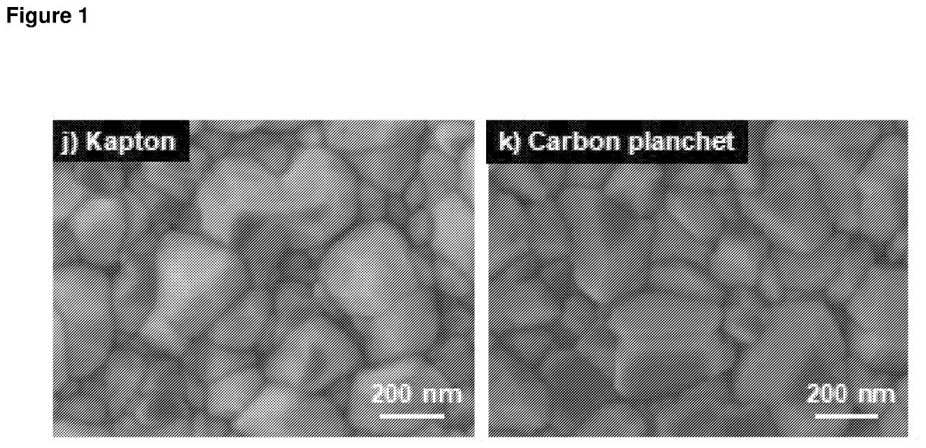

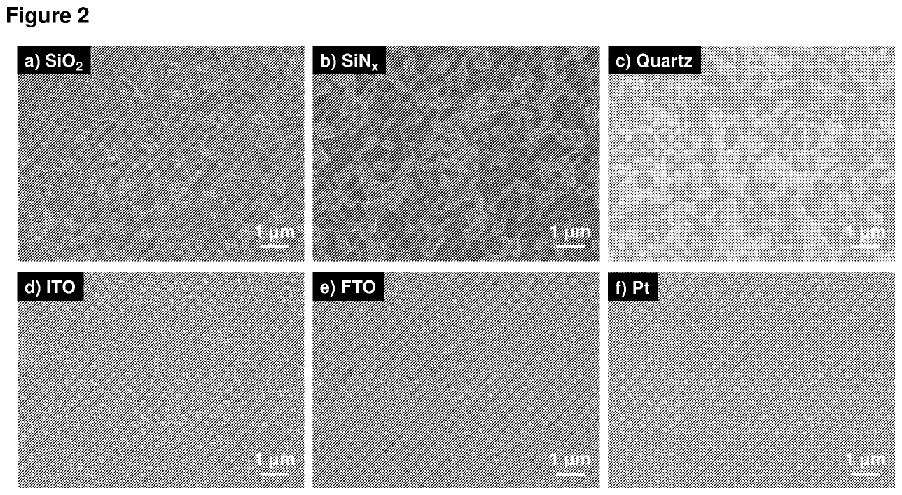

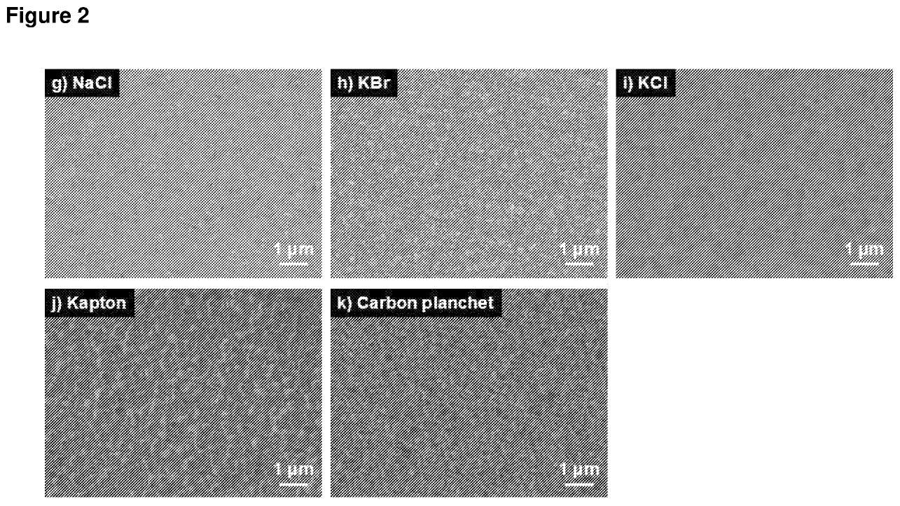

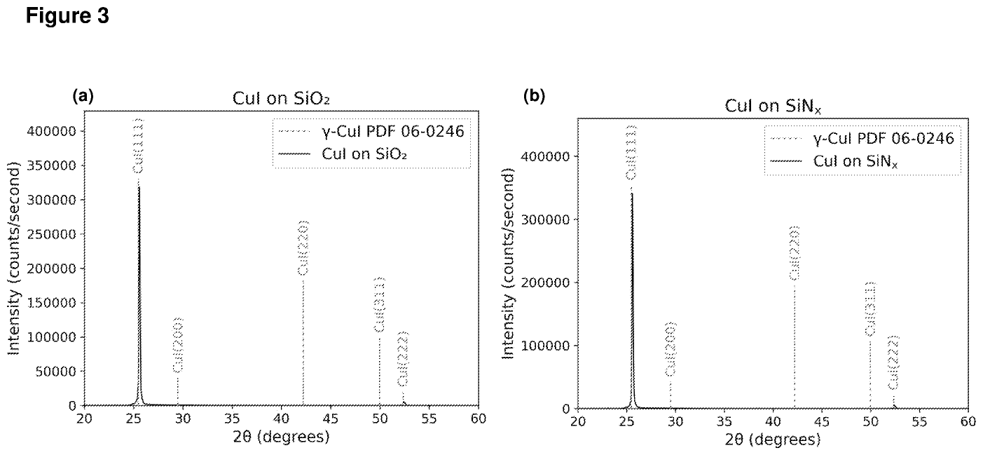

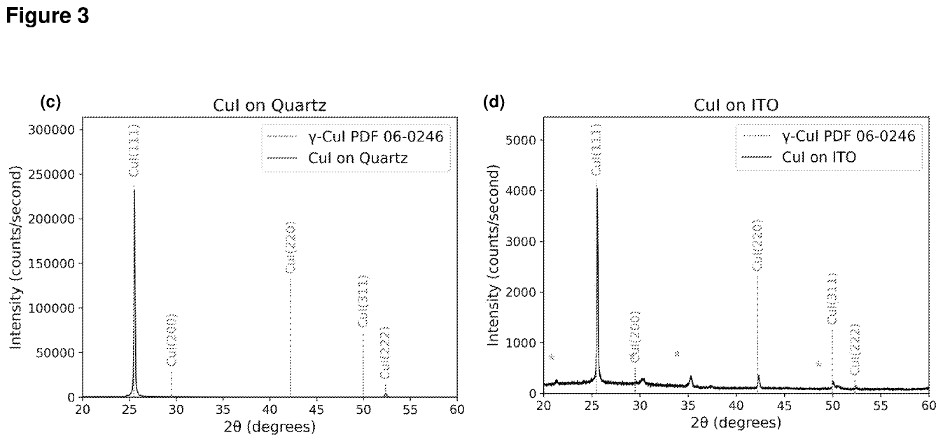

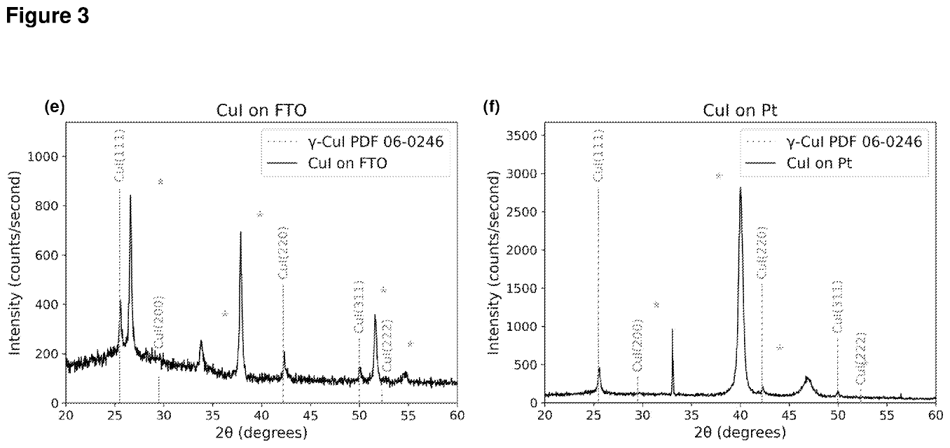

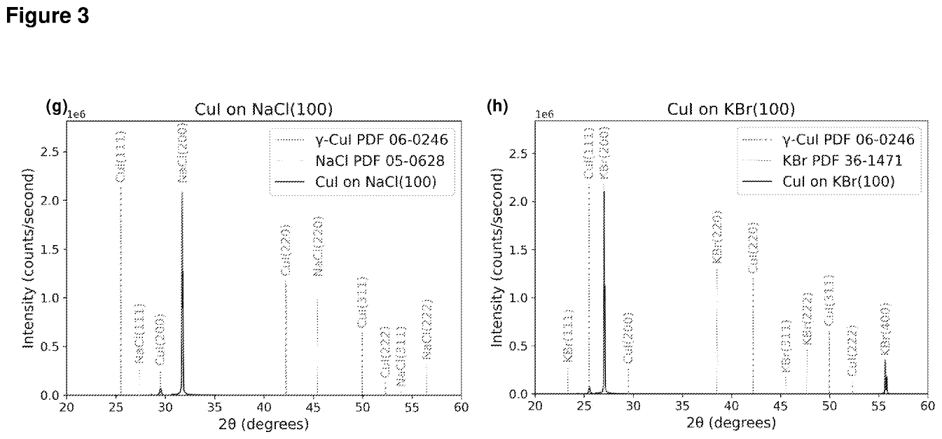

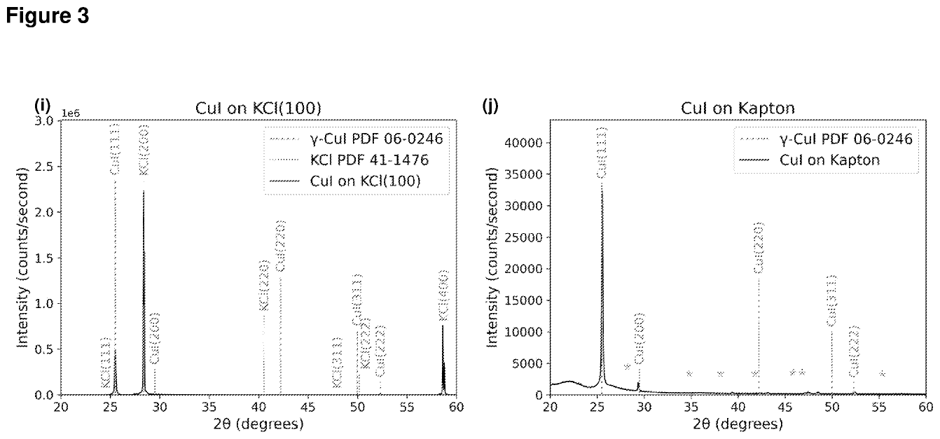

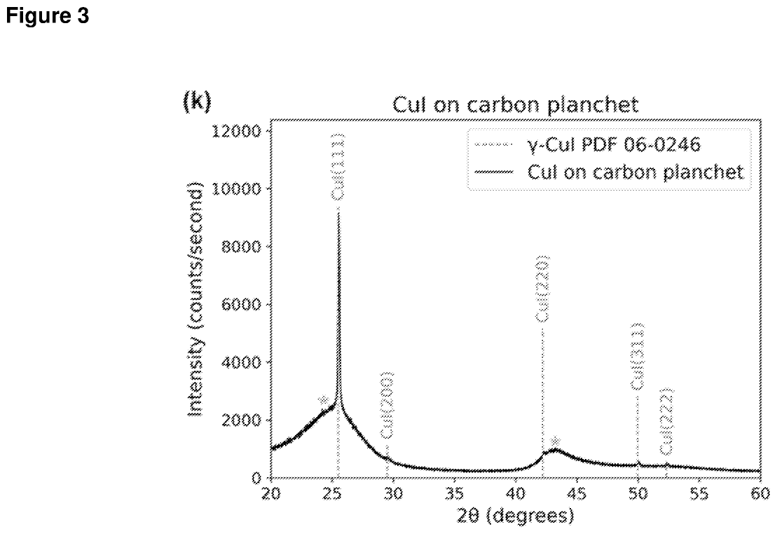

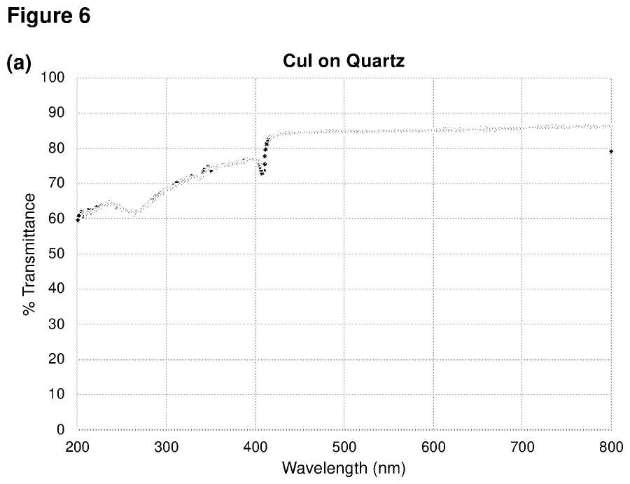

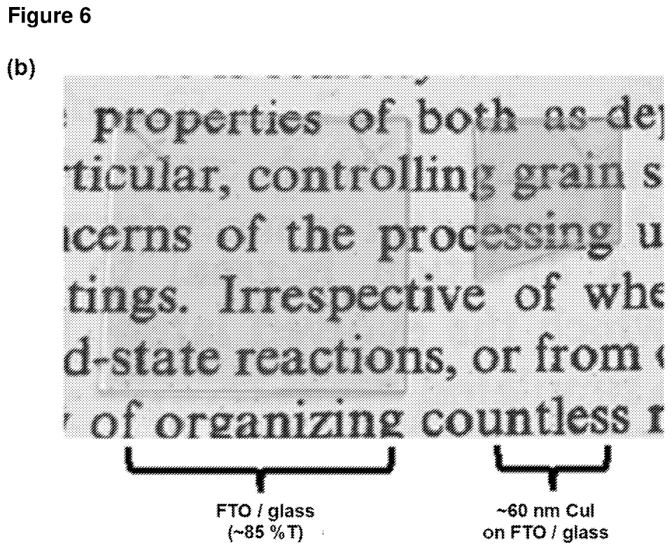

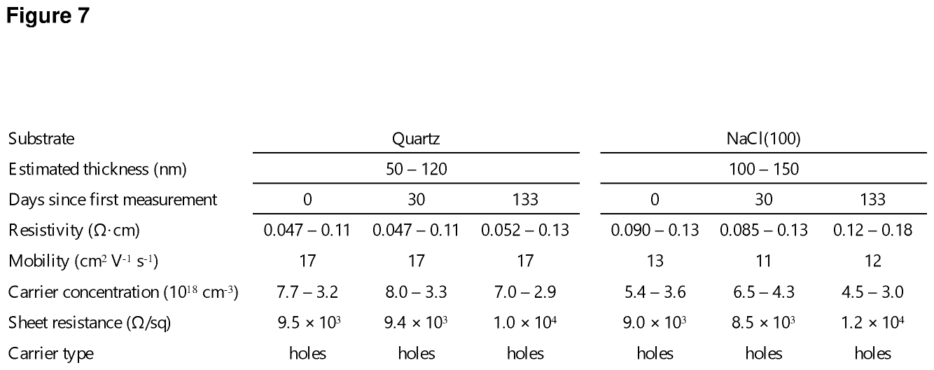

Herein, it is shown that CVD reaction between a volatile copper complex (e.g., an acetylacetonato copper(I) complex with a neutral ligand, e.g., vinyltrimethylsilane(hexafluoroacetylacetonato)copper(I), also referred to as Cu(hfac)(vtms) hereinafter) and a halosilane (e.g., iodotrimethylsilane (TMSI)) yielded zincblende CuI films on a wide variety of substrates including amorphous SiO₂, SiNₓ, quartz, ITO, FTO, Pt, NaCl(100), KBr(100), KCl(100), carbon (e.g., vitreous carbon), and polymers such as poly-oxydiphenylene-pyromellitimide (e.g., Kapton®) films. Scanning electron micrographs of such films are shown in FIGS. 1 and 2. X-ray diffraction (XRD), X-ray photoelectron spectroscopy (XPS), and Rutherford backscatter spectrometry (RBS) measurements were consistent with stoichiometric zincblende CuI films on all substrates except Pt, on which films are Cu-enriched (FIGS. 3, 4, 5 and Table 1). UV/Vis spectroscopy of CuI deposited on quartz demonstrates the expected optical properties (FIG. 6), and Hall effect measurements conducted on CuI films on quartz and NaCl(100) confirm that the electrical performance is as expected for zincblende CuI (FIG. 7). Films (layers) of copper halides (e.g., CuI) produced as described herein are continuous films on a broad variety of substrates. In some embodiments, the films are pinhole-free.

Deposition of Copper Halides from Volatile Copper Complexes and Halosilanes

The invention provides methods of depositing copper halides on a variety of substrates (e.g., a metal (e.g., Pt), a semiconductor (e.g., a perovskite film, silicon, organic semiconductors (e.g., polymeric semiconductors, organic photovoltaics, etc.), an optoelectronic material, a photovoltaic material, a dielectric (e.g., SiO₂ (e.g., amorphous silica or quartz) or SiNₓ), an interfacial layer, a sacrificial layer (e.g., NaCl, KCl, or KBr, e.g., crystalline), a transparent conducting material (e.g., ITO, FTO, conducting polymers such as PEDOT:PSS), or an adhesion layer, carbon (e.g., vitreous carbon, e.g., a carbon planchet), flexible polymers (e.g., polyimide (e.g., poly-oxydiphenyiene-pyromellitimide (e.g., Kapton®)) film or tape, polypropylene, cyclic olefin copolymer, polyethylene terephthalate, polyethylene, polyvinylchloride, polyetherimide, poly ether ketone, poly(methyl methacrylate), polydimethylsiloxane, etc.)).

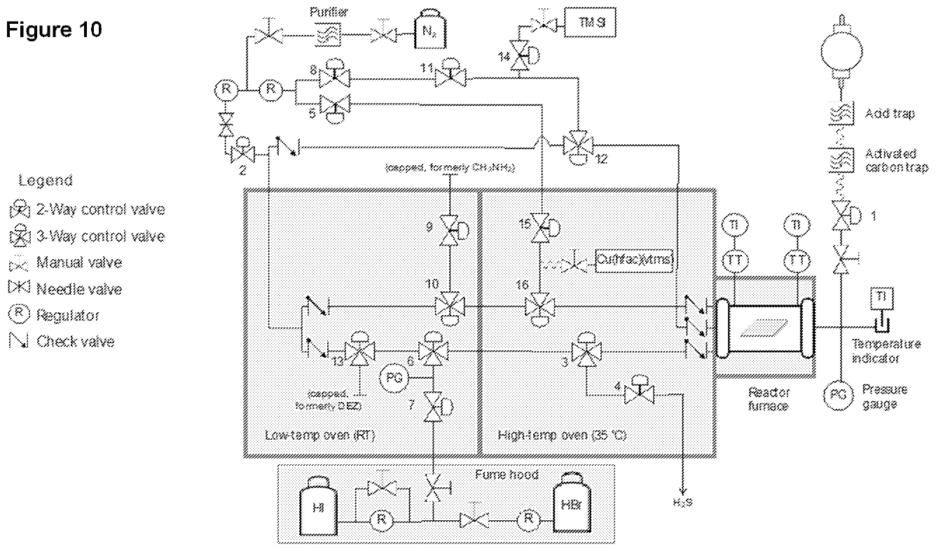

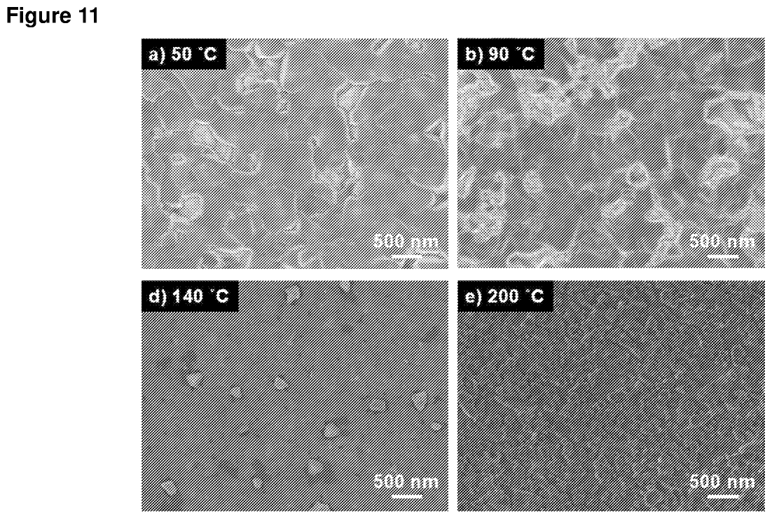

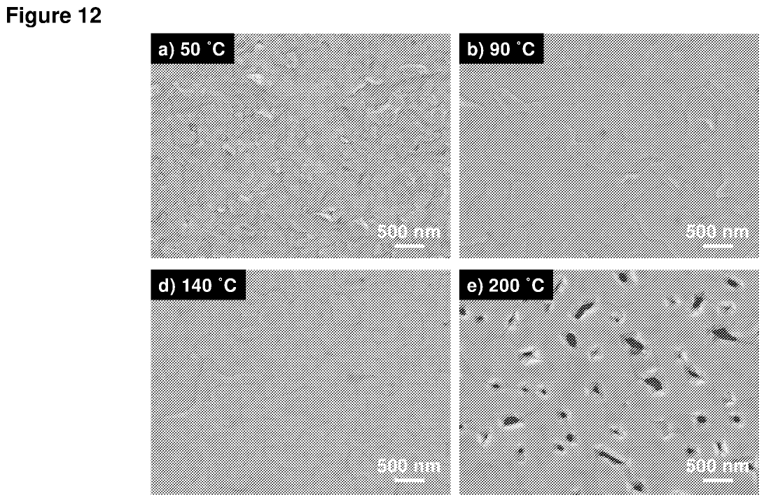

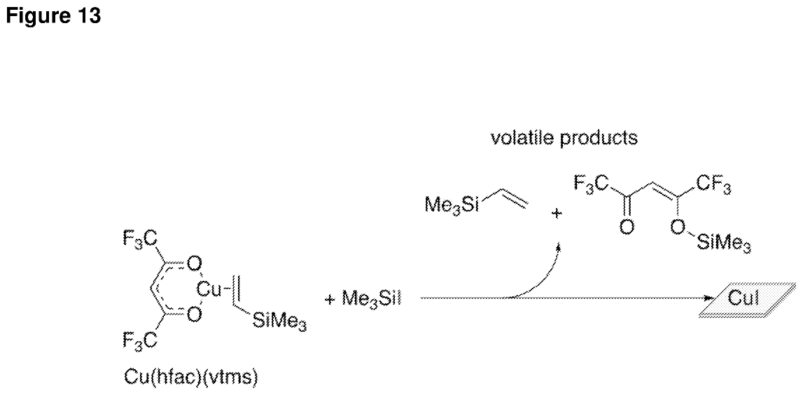

In methods of the invention, a volatile copper complex (e.g., an acetylacetonato copper(I) complex with a neutral ligand, such as Cu(hfac)(vtms) (vinyltrimethylsilane (hexafluoroacetylacetonato) copper(I)) and halosilanes (e.g., trialkylhalosilanes, e.g., trialkyliodiosilanes, e.g., trimethylsilane iodide) in the presence of the substrate, e.g., in a reactor as shown in FIG. 10. An exemplary deposition reaction is shown in FIG. 13. The copper complex and halosilane react together on the substrate to produce copper halide (e.g., CuI) on the substrate and volatile byproducts such as vinyltrimethyl silane and silyl ester of the acetylacetonato ligand, which can be subsequently removed in a purge step. The reaction and purge may be a cycle that can be repeated for as many times as needed to produce a film of the desired thickness.

In some embodiments, the deposition can be done in a “pulsed CVD” process, where both precursor vapors are introduced into the chamber without purging between the doses; then unreacted precursors and byproducts are purged out of the chamber (A-B-purge=1 cycle). In this process both vapors are in the reactor chamber at the same time. In other embodiments, the deposition may be done in a continuous CVD process, where both precursors continuously flow over the substrate. In some reactors, it may be advantageous for the substrate to be first exposed to the halosilane vapor. Alternatively, or in addition, the partial pressures of the copper complex and halosilane may be adjusted to have a large excess of the halosilane, for example a pressure of the halosilane vapor may be from 10 to 200 times (e.g., 10-40 times, 30-50 times, 25-50 times, 40-60 times, 50-100 times, 50-75 times, 60-80 times, 70-90 times, 80-100 times, 75-100 times, 80-160 times, 150-200 times, 100-125 times, 120-140 times, 125-150 times, 130-160 times, 140-170 times, 160-180 times, 175-200 times, etc.) that of a copper complex vapor. In some embodiments, a concentration of the halosilane vapor is from 10 to 500 times (e.g., 10-40 times, times, 25-50 times, 40-60 times, 50-100 times, 50-75 times, 60-80 times, 70-90 times, 80-100 times, 75-100 times, 80-160 times, 150-200 times, 100-125 times, 120-140 times, 125-150 times, 130-160 times, 140-170 times, 160-180 times, 175-200, 250-300 times, 200-325 times, 220-440 times, 225-350 times, 230-360 times, 240-370 times, 260-380 times, 300-400 times, 300-325 times, 320-340 times, 325-350 times, 330-460 times, 340-370 times, 360-480 times, 375-400 times, 350-500 times, 400-425 times, 420-440 times, 425-450 times, 430-490 times, 440-470 times, 450-500 times, 460-480 times, 475-500 times, 495-500 times, etc.) that of a copper complex vapor. In some embodiments, the plurality of cycles includes 10-50,000 cycles (e.g., 10-100, 50-500, 100-1000, 500-5000, 500-1500, 1,000-1,500, 1,000-2,000, 1,000-10,000, 1,500-3,000, 2,000-5,000, 2,500-5,000, 3,000-6,000, 5,000-10,000, 5,000-7,500, 6,000-9,000, 8,000-10,000, 7,500-15,000, 10,000-20,000, 15,000-30,000, 20,000-40,000, 25,000-30,000-40,000, 40,000-50,000, e.g., about 100, 500, 1,000, 2,000, 3,000, 4,000, 5,000, 10,000, 20,000, 30,000, 40,000, or 50,000 cycles). Deposition may be done at temperatures from 25° C. to 200° C. (e.g., 25° C. to 30° C., 25° C. to 50° C., 25° C. to 100° C., 50° C. to 100° C., 75° C. to 150° C., 125° C. to 150° C., 100° C. to 200° C., 100° C. to 120° C., 100° C. to 180° C., 150° C. to 200° C., 150° C. to 160° C., 150° C. to 175° C., 160° C. to 180° C., 180° C. to 190° C., 190° C. to 200° C., or 195° C. to 200° C., e.g., about 25° C., 30° C., 35° C., 40° C., 45° C., 55° C., 60° C., 75° C., 85° C., 95° C., 100° C., 110° C., 120° C., 130° C., 140° C., 150° C., 160° C., 170° C., 180° C., 190° C., or 200° C.). Deposition may be done with a flow of carrier gas, e.g., an inert gas such as N₂, He,

Ar, etc. Deposition may be performed at atmospheric pressure, under reduced pressure (e.g., from 10⁻⁶ Torr to 760 Torr, e.g., 10⁻⁶ Torr to 10⁻⁵ Torr, 10⁻⁵ Torr to 10⁻⁴ Torr, 10⁻⁴ Torr to 10⁻³ Torr, 10⁻³ Torr to 10⁻² Torr, 10⁻² Torr to 10⁻¹ Torr, 10⁻¹ Torr to 1 Torr, 10⁻¹ Torr to 10 Torr, 1 Torr to 10 Torr, 10 Torr to 100 Torr, 100 Torr to 500 Torr, 100 Torr to 750 Torr, e.g., about 0.01 Torr to 50 Torr, e.g., about 0.1-10 Torr, e.g., about 10 -6 Torr, 10 -5 Torr, 10 -4 Torr, 10 -3 Torr, 10 -2 Torr, 10 -1 Torr, e.g., about 0.1 Torr, 0.2 Torr, 0.3 Torr, Torr, 0.1 Torr, 0.2 Torr, 0.5 Torr, 0.7 Torr, 0.8 Torr, 0.9 Torr, 1 Torr, 10 Torr, 20 Torr, 30 Torr, 50 Torr, 100 Torr, 200 Torr, 250 Torr, 500 Torr, 600 Torr, 700 Torr, 750 Torr, etc.).

### Atomic Layer Deposition

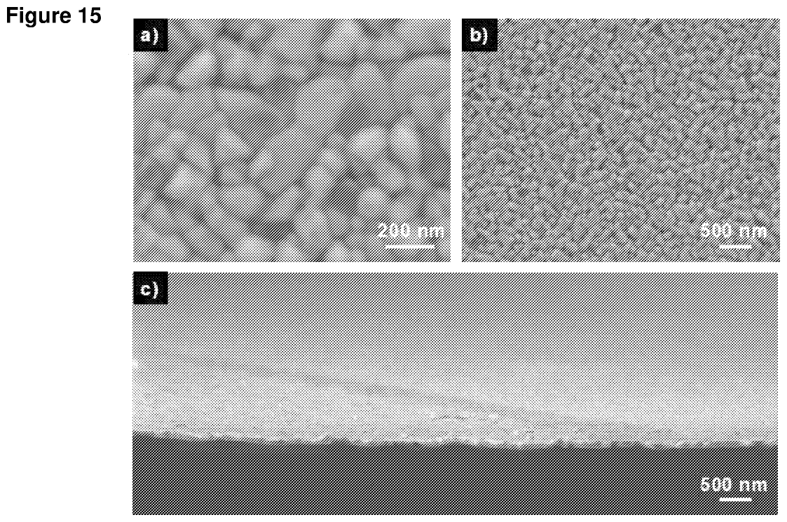

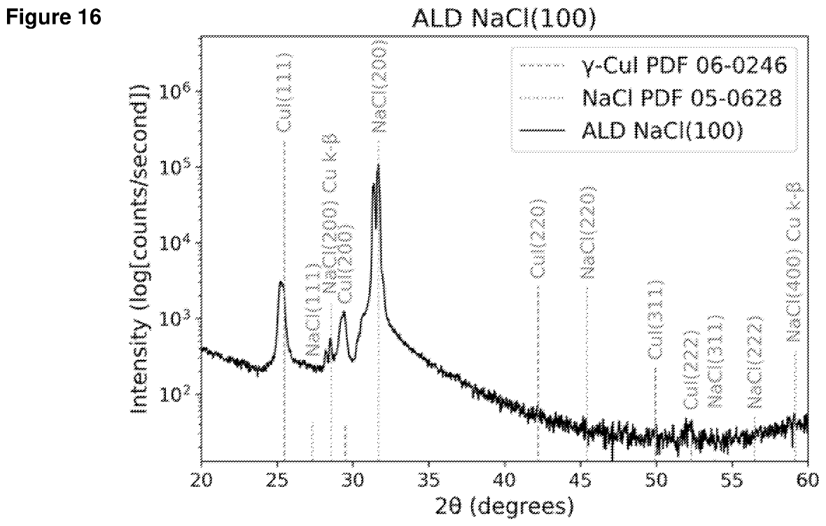

A method of growing films of copper halides (e.g., CuI) by atomic layer deposition is also provided. CuI was grown on NaCl(100) with Cu(hfac)(vtms) and TMSI, resulting in the film shown in FIG. 15, which was characterized by XRD, as shown in FIG. 16. The SEM and XRD data confirmed that copper halides can be grown in an ALD process.

In ALD methods of the invention, a substrate is subjected to alternating exposure to the halosilane and the copper complex separated by a purge to perform a cycle, which can, e.g., be repeated for as many cycles as need to produce a copper halide film of the desired thickness.

An exemplary cycle of closed valve ALD according to methods of the invention may include: a first precursor delivery pulse with a duration t₁; an incubation, where the first precursor is held in the reactor chamber, with a duration t₂; a purge of duration t₃, an evacuation step, where the chamber is evacuated back to base pressure, having a duration t₄, a second precursor (e.g., the copper complex, e.g., Cu(hfac)(vtms)) dose of duration t₅; a second precursor incubation of duration t₆; a final purge of duration t₇; and a final evacuation of duration t₈ in which the chamber is evacuated base pressure before the next cycle begins.

### Copper Complexes

Copper complexes suitable for use in the methods of the invention include any copper complex that can be transported in gas form to the substrate and that reacts with a halosilane to produce a copper halide. Exemplary copper complexes are Cu(I) complexes including an acetonato ligand, e.g., acetylacetonato, and a neutral ligand. An exemplary acetylacetonato ligand is the hexafluoroacetylacetonato ligand, which affords copper complexes with enhanced volatility. Other polyfluorocarbyl (e.g., perfluoroalkyl)-substituted acetylacetonato ligands are also considered, e.g., where one or both trifluoromethyl groups are substituted with a different polyfluorocarbyl group. Other exemplary ligands include acac=acetylacetonate (2,4-pentanedionate), tfac=trifluoroacetylacetonate (1,1,1-trifluoro-2,4-pentanedionate), and pfac=perfluoroacetylacetonate (1,1,1,3,5,5,5-heptafluoropentane-2,4-dionate). Corresponding diketimine, beta-ketoiminate, and diketonate ligands may also be employed as ligands. Secondary amines (e.g., having formula NHR′R″, where R′ and R″ are independently hydrocarbyl (e.g., optionally substituted C₁₋₆ alkyl), polyfluorocarbyl (e.g., optionally substituted C₁₋₆ perfluoroalkyl), or aryl (e.g., phenyl)), may also be employed, preferably amines that form volatile Cu(I) amide complexes with copper and/or are themselves volatile.

The neutral ligand may be one that binds to copper(I) in order to make the volatile precursor complex. The neutral ligand may be any ligand that is sufficiently labile to leave the copper center in the presence of a halosilane. Preferably, a neutral ligand should not react with the TMSI to form a non-volatile product. Preferably, the neutral ligand is itself volatile. Preferably the neutral ligand is one that, when removed, is itself a volatile species, e.g., a gas or liquid or solid with a high vapor pressure at the temperatures and pressures of the deposition reaction. In some embodiments, the copper complex includes a vinyltrimethylsilane (vtms) ligand. In some embodiments, the copper complex is Cu(hfac)(L), where L is a neutral ligand. In some embodiments, L is a phosphine, an alkene (e.g., vtms), or an alkyne (e.g., 2-butyne, bis(trimethylsilyl)acetylene, 2-methyl-1-hexen-3-yne or hex-3-yn-1-ene). Exemplary phosphine ligands include compounds of the formula R₃P, where each R is independently a hydrocarbyl or aryl group, e.g., Me3P. Exemplary alkenes include ethene, propylene, 1-butene, 2-butene, and isobutylene, 1-pentene, 2-pentene, 2-methyl-1-butene, 3-methyl-1-butene, 2-methyl-2-butene, 1-hexene, 2-hexene, 3-hexene, 2-methyl-1-pentene, 3-methyl-1-pentene, 4-methyl-1-pentene, 2-methyl-2-pentene, 3-methyl-2-pentene, 4-methyl-2-pentene, 2,3-dimethyl-1-butene, 3,3-dimethyl-1-butene, 2,3-dimethyl-2-butene, 2-ethyl-1-butene, vinyltrimethylsilane (vtms), triethylvinylsilane, allyltrimethylsilane, 1,5-cyclooctadiene, etc. Alkenes, alkynes, and phosphines may be optionally substituted, or include hydrocarbyl groups that are optionally substituted. Compounds aromatic compounds and compounds with aryl groups may also act as η-2 hapticity ligands, i.e., act as alkenes, in complexes of the invention. Exemplary aromatic compounds that can be neutral ligands in complexes of the invention include benzene and toluene. In some embodiments, the copper complex is Cu(hfac)(vtms) and the halosilane is Me₃Sil.

### Deposition of Copper Halides on Perovskite Absorber Materials

Methods of the invention are particularly advantageous for the production of hole transport materials in perovskite solar cells. A representation of a perovskite solar cell is shown in FIG. 13. In perovskite solar cells an n-type electron transport layer (also known as an electron transport material, ETM) helps drive electrons to the electron collection layer, and a p-type hole transport layer (also known as a hole transport material, HTM) helps drive holes to the electron injection layer. These layers can also separate bound charges of excitons at their respective interface with the perovskite absorber. The ETM and HTM also act as blocking layers for holes and electrons, respectively in the perovskite absorber. While there are a great number of ETMs, suitable HTMs are rarer. Copper compounds such as CuI can be an excellent HTM if it can be applied to the perovskite without damaging the perovskite.

Because the processes described herein can run at very low temperatures (at least as low as 50° C., e.g., 25-50° C., e.g., about 25° C., 30° C. 35° C., or 45° C.), they allow deposition atop temperature-sensitive substrates including flexible polymers and perovskite absorber materials. In fact, we have also demonstrated use of this technique to deposit CuI atop the perovskite absorber material methylammonium lead trisiodide (MAPbI₃).

CVD and ALD deposition atop perovskite absorber materials is challenging; it typically results in some degradation of the underlying perovskite absorber substrate due to a combination of elevated deposition temperatures and reaction of the perovskite itself with precursors. Protective interlayers are frequently required to protect the perovskite.

Perovskite solar cell materials are organometallic compounds that absorb light to produce excitons and/or free electrons and holes and which have an ABX₃ crystal structure (i.e., a perovskite structure), where A and B are cations, and X is an anion. Exemplary perovskite solar cell materials may have the general formula QMX₃, where Q is a cationic counterion, e.g., an ammonium or Group 1 (alkali metal) cation (e.g., Cs⁺) counterion, or a mixture of counterions, e.g., a mixture of ammonium counterions or a mixture Group 1 metal cations, or a mixture of ammonium and Group 1 metal cation counterions, X is a halide or a combination of halides (e.g., a I₃, I₂Br, IBr₂, or a having a non-integer stoichiometric ratio, etc.), and M is a metal (e.g., Pb, Cs, Sn) or a combination thereof or combination (e.g., with a non-integer stoichiometric ratio) of metals (e.g., Pb1-xSnₓ, where x=0.01-0.99). The perovskite may be, e.g., a methylammonium tin trishalide, methylammonium lead trishalide, cesium tin trishalide, cesium lead trishalide, formamidinium tin trishalide, formamidinium lead trishalide, or a combination thereof. The perovskite absorbing layer may be MAPbBr₃, MAPbI₃, FAPbI₃, MAPb₁₋ₓSnₓI₃, or MASnI₃, where ‘MA’=methylammonium and ‘FA’=formamidinium. In some embodiments, the perovskite is MAPbI₃. A perovskite may include a mixture of Q counterions, a mixture of M metals, and a mixture of X halides, e.g., (Q′ₐQ″_{b}Q″′_{c})M═_{d}M″ₑ(X′_{f}X″_{g}X″′ₕ)₃, where a=0 to 1, b=0 to 1, c=0 to 1 and (a+b+c)=1, where d=0 to 1, e=0 to 1, and (d+e)=1, and where f=0 to 1, g=0 to 1, h=0 to 1 and (f+g+h)=1, e.g., (MAₐFA_{b}Cs_{c})Pb_{d}Snₑ(Cl_{f}Br_{g}Iₕ)₃, where a=0 to 1, b=0 to 1, c=0 to 1 and (a+b+c)=1, where d=0 to 1, e=0 to 1, and (d+e)=1, and where f=0 to 1, g=0 to 1, h=0 to 1 and (f+g+h)=1.

Perovskite solar cells of the invention may include any perovskite material described herein, or known in the art, in contact with a copper halide (e.g., CuI) as a p-type hole transport material. Perovskite solar cells of the invention can have little to no degradation resulting from the deposition of the copper halide. Such degradation (or its absence) may be detected/confirmed by XRD. For example, by the relative areas of an XRD peak of the pristine perovskite to that of a reduction product of its degradation, e.g., when the perovskite is a QMX₃ perovskite (e.g., MAPbI₃), the perovskite may have a ratio of MX₂ (i.e., the degradation product, e.g., PbI₂) to QMX₃ of less than 22% (e.g., 22-15%, 20-10%, 15-10%, 10-5%, 10-1%, 5-2%, 2-1%, 1-0%, 0.5-0.1%, 0.1-0%, etc., e.g., less than 10%, 5%, or 1%., e.g., about 10%, about about 2%, about 1%, or about 0.5%. The relative concentrations of pristine perovskite and any degradation product may be determined by other means, e.g., XPS, wide angle x-ray scattering (WAXS), secondary ion mass spectrometry (SIMS), etc. The perovskite absorber layer may show no degradation by XRD or any other technique.

Perovskite solar cells of the invention may include any electron injection layer that is suitable for the copper halide p-type semiconductor (e.g., chemically compatible with CuI). The electron injection layer may be, e.g., a reflective, transparent, or semitransparent electron injection layer. A reflective electron injection layer may increase the cell efficiency by providing a second chance for a photon that was not absorbed to be absorbed. Alternatively, a transparent or semitransparent electron injection layer may allow the solar cell to be used in a smart window or other solar cell application where it is necessary to let some light through.

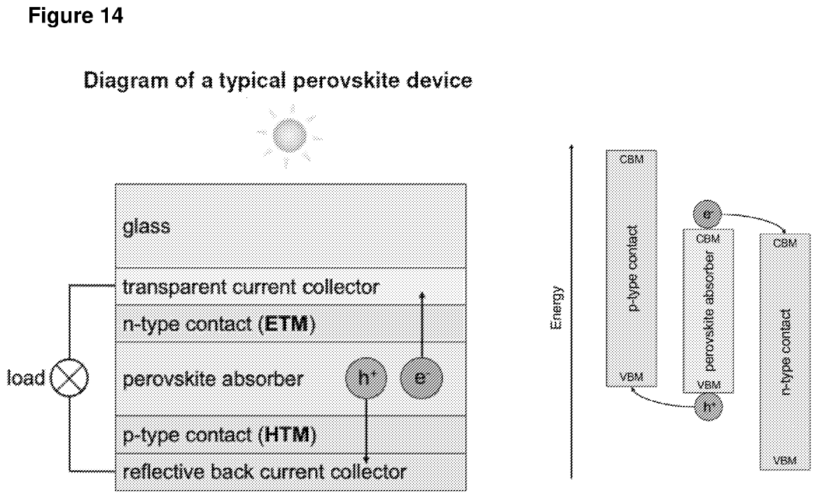

Perovskite solar cells of the invention may include any electron transport layer that is suitable for the particular perovskite absorber layer (e.g., having an appropriate band offset, as shown in FIG. 14).

Exemplary electron collection layer materials include ITO, FTO, doped zinc oxide, In or Sn-doped cadmium oxide, Zn₂SnO₄, ZnSnO₃, Zn₂In₂O₅, Zn₃In₂O₆, Cd₂SnO₄, CdSnO₃, CdIn₂O₄, MgIn₂O₄, GaInO₃, Sn or Ge-doped gallium oxide, Y-doped CdSb₂O₆, Zn₂In₂O₅—In₄Sn₃O₁₂, CdIn₂O₄—Cd₂SnO₄, or ZnO—CdO—In₂O₃—SnO₂, or combinations thereof.

### Other Devices

Methods of the invention are particularly advantageous for the fabrication of any device that requires, e.g., continuous layers of high-quality, transparent, p-type materials. Other devices which can be produced using the methods of the invention include LEDs, TFTs, LCDs, diodes, photosensors, smart windows, touchscreens, etc.

Devices may include a composition of the invention having a substrate (e.g., a metal, a semiconductor, an optoelectronic material, a photovoltaic material, a dielectric, an interfacial layer, a sacrificial layer, a templating layer, or an adhesion layer) and a copper halide layer (e.g., a CuI layer) in physical contact with the substrate. The substrate can be a material that physically or chemically degrades at temperatures between 35° C. and 200° C. (e.g., 35° C. to 40° C., 35° C. to 50° C., 35° C. to 100° C., 50° C. to 100° C., 75° C. to 150° C., 125° C. to 150° C., 100° C. to 200° C., 100° C. to 120° C., 100° C. to 180° C., 150° C. to 200° C., 150° C. to 160° C., 150° C. to 175° C., 160° C. to 180° C., 180° C. to 190° C., 190° C. to 200° C., or 195° C. to 200° C., e.g., about 25° C., 30° C., 35° C., 40° C., 45° C., 50° C., 55° C., 60° C., 75° C., 85° C., 95° C., 100° C., 110° C., 120° C., 130° C., 140° C., 150° C., 160° C., 170° C., 180° C., 190° C., or 200° C.), or, e.g., of materials that degrade at temperatures over 100° C. and/or is chemically reactive to hydrogen halides and/or copper complexes at or above room temperature. Such compositions may include the copper halide as a defect (e.g., pinhole)-free continuous film.

Exemplary substrates include carbon (e.g., vitreous carbon, e.g., a carbon planchet), polymeric materials (e.g., flexible materials such as a polyimide (e.g., poly-oxydphenyiene-pyromeilitimide (e.g., Kapton®)) film or tape, polypropylene, cyclic olefin copolymer, polyethylene terephthalate, polyethylene, polyvinylchloride, polyetherimide, poly ether ketone, poly(methyl methacrylate), polydimethylsiloxane, etc.), perovskite materials (e.g., any perovskite material described herein, e.g., methylammonium lead trisiodide perovskite films, e.g., perovskite LEDs).

The substrate may be or comprise one or more layers comprising one or more of ITO, FTO, doped zinc oxide, In or Sn-doped cadmium oxide, Zn₂SnO₄, ZnSnO₃, Zn₂In₂O₅, Zn₃In₂O₆, Cd₂SnO₄, CdSnO₃, CdIn₂O₄, MgIn₂O₄, GaInO₃, Sn or Ge-doped gallium oxide, Y-doped CdSb₂O₆, Zn₂In₂O₅—In₄Sn₃O₁₂, CdIn₂O₄—Cd₂SnO₄, or ZnO—CdO—In₂O₃—SnO₂.

### EXAMPLES

### Example 1

### Growth of CuI on Various Substrates by CVD

CuI depositions were performed in a custom-built hot-walled ALD reactor, shown in blueprint format in FIG. 10 and described in greater detail elsewhere (Chang, C. M., et al., Chem. Mater., 2021, 33 (4), 1426-1434; and US 2022/0380893 A1). Valve numbers referenced herein are those shown in FIG. 10. For this work, a small branch with a new pneumatic ALD valve (valve 14) was installed to accommodate the TMSI bubbler and create a trap volume for TMSI vapor between valves 11, 12, and 14.

TMSI was purchased and used as received (Sigma Aldrich, 97%). The copper precursor was purchased from Gelest as a mixture of Cu(hfac)(vtms) and Cu(hfac)₂; Cu(hfac)(vtms) was isolated from the mixture as described in Chang, C. M., et al., Chem. Mater., 2021, 33 (4), 1426-1434. Both precursors are liquid at room temperature. For depositions, TMSI was stored in a glass-bottomed stainless-steel bubbler at room temperature, and Cu(hfac)(vtms) was stored in a glass bubbler in a 35° C. oven unless otherwise noted. Both precursors were loaded into their respective bubblers in a nitrogen-filled glovebox, and manual valves sealing the bubblers were closed before removing from the glovebox and installing in the reactor. To remove any atmosphere introduced into the reactor lines during bubbler installation, the affected reactor line was purged overnight by repeatedly filling with nitrogen and then evacuating to base pressure (typical base pressure in this reactor, under active vacuum with just valve 1 open, is ˜20 mTorr). Once purging was complete, the precursor line was evacuated to base pressure, and the bubbler manual valve was opened to allow evacuation of the trapped glovebox nitrogen atmosphere, until the measured pressure stabilized (typically <30 s of active vacuum).

CuI depositions were typically run as pulsed-CVD (p-CVD), where in a single cycle both precursors were delivered into the chamber in pulses separated by 0.1 s, allowing both precursors to occupy the chamber simultaneously, followed by a purge step before the subsequent cycle. Purge nitrogen pressure was typically set to 0.7 Torr by opening valves 1 and 2 and adjusting the upstream nitrogen regulator until the pressure gauge at the reactor outlet read 0.7 Torr.

A nitrogen carrier gas was used to deliver Cu(hfac)(vtms) to the reactor chamber; the TMSI line was also equipped with a nitrogen carrier gas, but its use was generally found to be unnecessary given the high vapor pressure of TMSI. Cu(hfac)(vtms) carrier gas pressure was typically set to 10 Torr; this was set by closing the manual valve on the Cu(hfac)(vtms) bubbler and opening valves 1, 5, 15, and 16, then adjusting the upstream nitrogen regulator until the pressure reading at the reactor chamber outlet was 10 Torr (see, FIG. 10). Valve 5 was closed, and the line was evacuated to base pressure before closing valves 15 and 16 and re-opening the bubbler manual valve. In most cases, to dose a mixture of Cu(hfac)(vtms) and nitrogen carrier gas into the reactor chamber, valves 5, 15, and 16 were opened for 0.5 s each with 0.1 s wait between each valve opening, so that carrier nitrogen was delivered to the trap volume between valves 5 and 15, then to the bubbler and trap volume between valves 15 and 16 where it mixed with Cu(hfac)(vtms) vapor, and then the mixture of Cu(hfac)(vtms) vapor and nitrogen was delivered to the reactor chamber upon the opening of valve 16.

For TMSI delivery without carrier gas, typical delivery involved opening valve 14 for 0.5 s, waiting 0.1 s, then opening valve 12 for 0.5 s to deliver the trapped TMSI vapor to the reactor. Here the trap volume is defined as the tube volume between valves 11, 12, and 14. In some cases, if a larger dose of TMSI was desired, valve 14 was kept open for the duration of the deposition, and valve 12 was pulsed so that TMSI vapor was delivered directly from the bubbler headspace into the reactor chamber; this effectively creates a larger TMSI trap volume which includes the bubbler headspace and all the tubing between valves 11 and 12, rather than just the tubing between valves 11, 12, and 14 (this method was used to provide increased TMSI dosing in depositions on MAPbI₃ perovskite absorbers; for even greater increases in TMSI dose, valve 12 was held open for longer than 0.5 s).

Pulsed-CVD depositions were run in either “closed valve” or “open valve” mode. In one cycle of closed valve mode p-CVD, the reactor chamber is evacuated, then the vacuum valve (1) is closed, and the precursors are dosed into the reactor chamber 0.1 s apart. Dosing is followed by a “wait time” where both precursors remain in the chamber, and then the vacuum valve is opened, and the chamber is purged with nitrogen. The time sequence of a single cycle of open valve p-CVD may be described as t₁-t₂-t₃-t₄-t₅-t₆, where t₁ is the duration of the first precursor delivery pulse, t₂ is the wait time between precursor delivery pulses, t₃ is the is the duration of the second precursor delivery pulse, t₄ is the “incubation time” in which both precursors are held in the reactor chamber to react, is the purge time where purge nitrogen is flowed into the chamber under active acuum, and t₆ is the evacuation time where the chamber is evacuated back down to base pressure. A typical closed-valve p-CVD recipe uses the timing sequence 0.5-0.1-0.5-5-10-21.2, given in seconds. Here, the duration of one closed-valve cycle is 37.3 s, and 1000 cycles can be run in about 10 h 22 m.

During open valve mode, purge nitrogen is constantly flowed through the reactor chamber (typically 0.7 Torr purge pressure). In one cycle in open valve mode p-CVD, the precursors are dosed into the reactor chamber 0.1 s apart while the chamber is continuously purged. Precursor dosing causes a pressure rise in the chamber; the reactor is purged until chamber pressure returns to purge pressure, and then the next p-CVD cycle begins. The time sequence of a single cycle of open valve p-CVD may be described as t₁-t₂-t₃-t₄, where t₁ is the duration of the first precursor delivery pulse, t₂ is the wait time between precursor delivery pulses, t₃ is the duration of the second precursor delivery pulse, and t₄ is the purge time before the next cycle begins. A typical open-valve p-CVD recipe uses the timing sequence 0.5-0.1-0.5-11.2, given in seconds. Here, the duration of one open-valve cycle is 12.3 s, and 1000 cycles can be run in about 3 h 25 m.

The order of precursor delivery and the use of closed vs. open valve mode were found to affect deposition results, with the best results obtained when TMSI was delivered before the Cu(hfac)(vtms)/carrier nitrogen mixture in open-valve mode. This can be explained by considering the relative pressures of the precursor doses: when delivered to the evacuated reactor chamber under static vacuum, a typical TMSI dose (0.5 s valve 14 pulse, 0.1 s wait, 0.5 s valve 12 pulse) delivers <1 Torr TMSI vapor, as measured in the reactor, whereas a typical Cu(hfac)(vtms) dose (0.5 s valve 5 pulse, 0.1 s wait, s valve 15 pulse, 0.1 s wait, 0.5 s valve 16 pulse) delivers >5 torr Cu(hfac)(vtms)/N₂ mixture (mostly N₂). In closed valve mode, delivering Cu(hfac)(vtms)/N₂ first creates a pressure gradient that does not favor TMSI delivery to the reactor chamber when TMSI valve 12 is opened. Thus, very little TMSI is delivered, and little CuI can be deposited. When TMSI is delivered first, the pressure gradient favors Cu(hfac)(vtms)/N₂ delivery to the chamber once Cu(hfac)(vtms) valve 16 is opened, and more CuI can be deposited. However, the pressure gradient in this case still does not appear strong enough to provide high growth rates. Instead, the best results were obtained in open valve mode, where each precursor is delivered to the chamber under active vacuum, which appears to enable more efficient delivery of both precursors to the chamber and yields higher CuI growth rates. Growth rates are particularly high when TMSI is delivered first in open valve mode, presumably because significantly more TMSI is delivered (in all cases, Cu(hfac)(vtms) is the limiting reactant), and because the transient pressure increase in the chamber upon TMSI delivery is slow to return to purge pressure, indicating that TMSI is not purged from the chamber very quickly, whereas the transient pressure rise for Cu(hfac)(vtms) delivery is smaller and briefer, indicating that the relatively small quantity of Cu(hfac)(vtms) delivered to the chamber is purged away quickly and has a better chance of reacting with TMSI to yield CuI if TMSI is present in the chamber upon Cu(hfac)(vtms) delivery.

### Example 2

### Characterization of CuI films

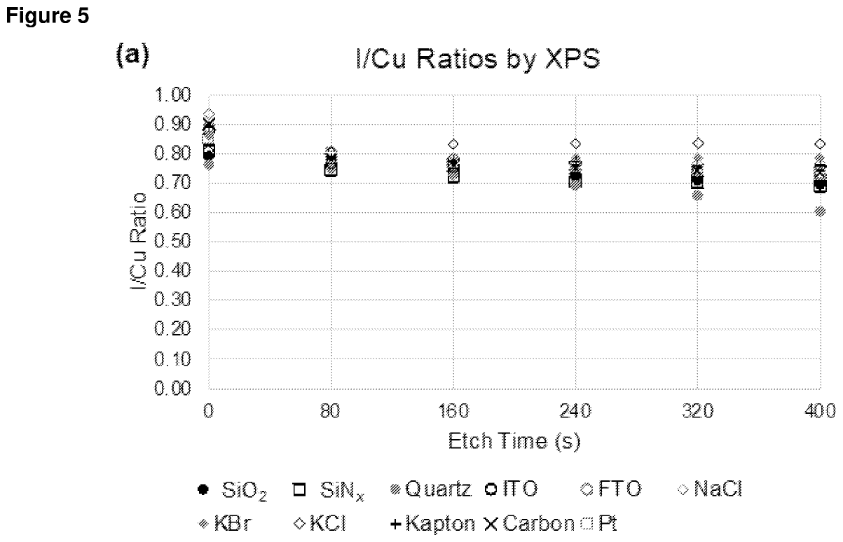

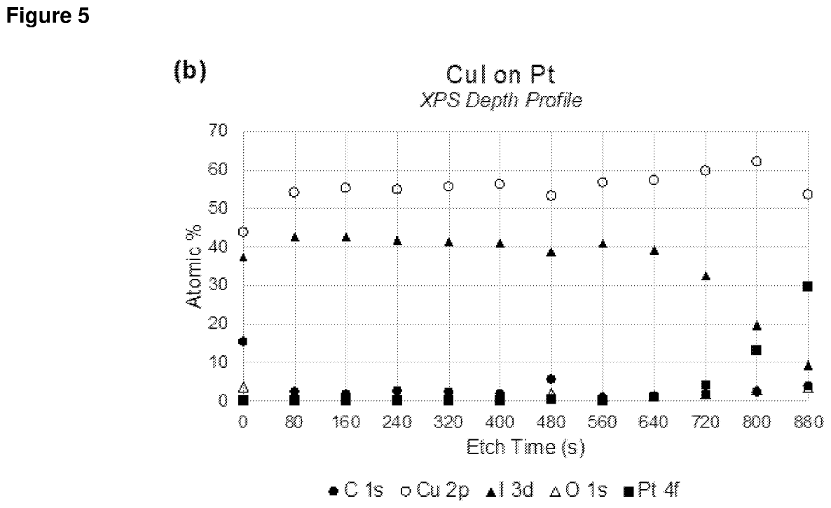

FIGS. 1 and 2 show scanning electron micrographs of CuI films grown on various substrates from 1000 cycles of open valve p-CVD with TMSI delivered before Cu(hfac)(vtms), using the timing sequence described above (0.5-0.1-0.5-11.2), with a substrate temperature of 50° C. Based on film thicknesses estimated from SEM cross sections, average growth rates observed on each substrate under these conditions, given in A/cycle, were: 1.3 (SiO₂), 1.3 (SiNₓ), 1.2 (quartz), 0.7 (ITO), 1.0 (FTO), 1.3 (Pt), 1.5 (NaCl(100)), 2.2 (KBr(100)), and 2.8 (KCl(100)). The CuI growth rate on carbon planchet and Kapton® are not reported due to difficulty in cleaving these substrates. For rough films and/or substrates, reported average growth rates are for the maximum CuI grain thickness observed in the cross section. Note that films grown on Pt are shown by RBS to be Cu-enriched, with XPS indicating greater Cu concentrations closer to the Pt-CuI interface (FIG. 5, Table 1).

FIGS. 1 and 2 show scanning electron micrographs of CuI films grown at a range of temperatures (50, 90, 140, and 200° C.) on SiO₂ and NaCl(100), respectively. On SiO₂, films were generally observed to be continuous, with large, flat, [111]-oriented CuI grains only at lower deposition temperatures (50° C., 90° C.). At higher temperatures, the material deposited on SiO₂ forms crystallites but not continuous films. On NaCl, films appear continuous by SEM at 140° C., with films deposited at higher temperatures appearing smoother. At 200° C., films grown on NaCl are no longer continuous but rather contain voids visible by SEM.

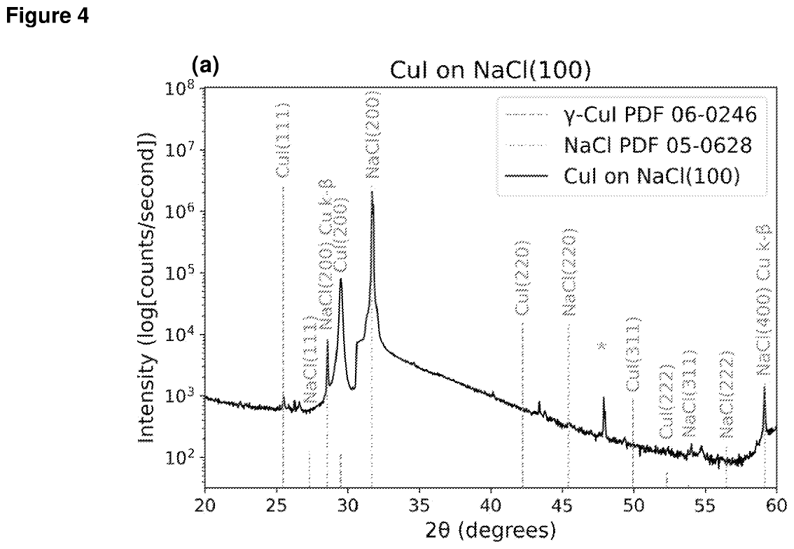

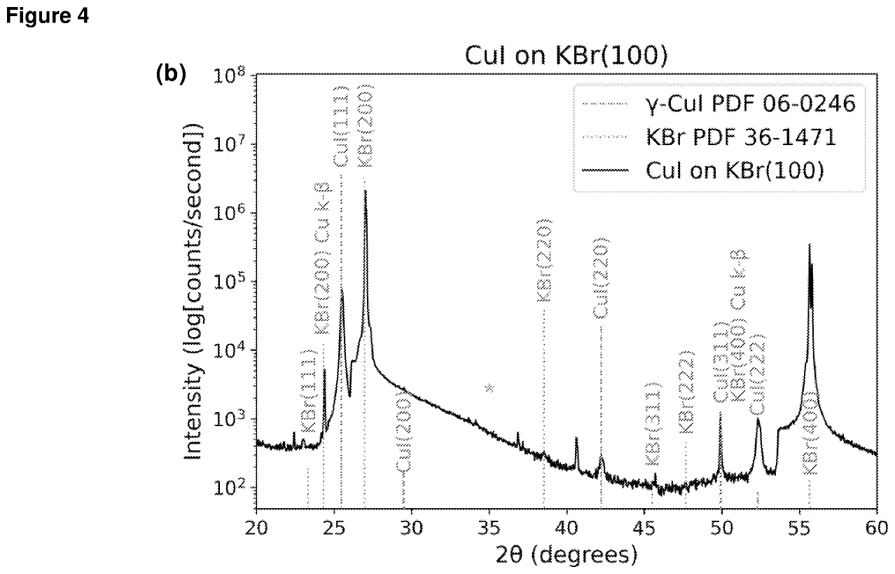

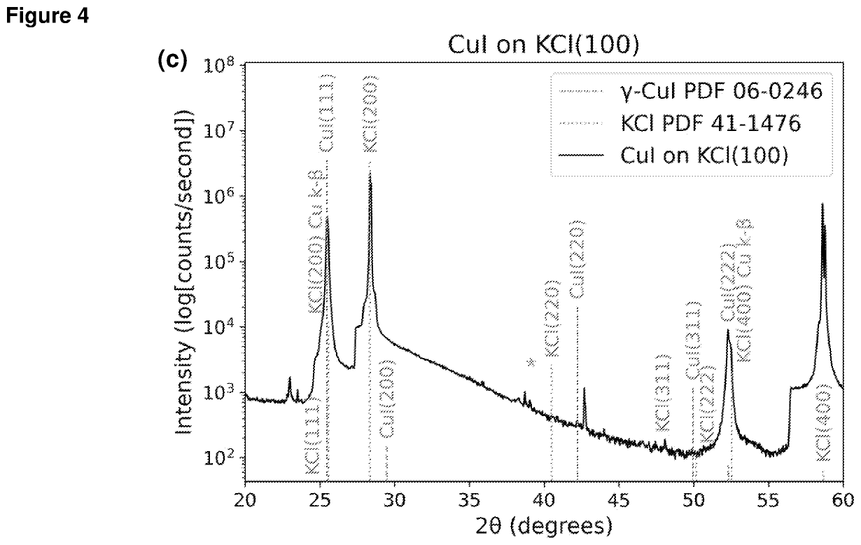

X-ray diffractograms of films grown at 50° C. from 1000 cycles of TMSI-first open valve p-CVD all indicate the presence of zincblende (γ) CuI (FIGS. 3 and 4). On certain substrates, γ-CuI was observed to have a preferential orientation: films on SiO₂, SiNₓ, quartz, KCl(100), and Kapton® are [111]-oriented; films grown on NaCl(100) are [100]-oriented; films grown on ITO, FTO, Pt, KBr(100) and carbon planchet display strong 111 reflections, but small peaks corresponding to other γ-CuI reflections are also observed. Note that in FIG. 4(c) the KCl 200 and 400 Cu k-β and CuI 111 and 222 Cu k-α reflections occur near the same angles and are not resolved, but compared to a KCl(100) control the peaks are significantly broadened, suggesting the presence of 111-oriented γ-CuI.

Film compositions were evaluated by XPS and RBS (FIGS. 3-5, Table 1).

Table 1 shows aerial densities of Cu and I determined by Rutherford backscatter spectrometry for CuI grown from 1000 cycles of open-valve pulsed CVD reaction between Cu(hfac)(vtms) and TMSI on Pt, SiO₂, and vitreous carbon planchet.

| | Copper (Cu) | Iodine (I) | | |
|---|---|---|---|---|
| Substrate | (×10¹⁵ cm⁻²) | (×10¹⁵ cm⁻²) | I/Cu | Deposition Details |
| Pt | 74 | 56 | 0.76 | 1000 cycles Cu-first open |
| | | | | valve p-CVD, 90° C. |
| | | | | (timing sequence: |
| | | | | 0.5-0.1-0.15-11.25) |
| SiO₂ | 140 | 140 | 1.00 | 1000 cycles TMSI-first |
| | | | | open valve p-CVD, 50° C. |
| | | | | (timing sequence: |
| | | | | 0.5-0.1-0.5-11.2) |
| Carbon | 330 | 330 | 1.00 | 1000 cycles TMSI-first |
| | | | | open valve p-CVD, 50° C. |
| | | | | (timing sequence: |
| | | | | 0.5-0.1-0.5-11.2) |

XPS is not expected to provide absolute quantification without calibration; select films were also evaluated by RBS in order to verify stoichiometry and calibrate the XPS measurements. Per RBS, CuI films deposited on SiO₂ and carbon planchet are stoichiometric CuI. Films deposited on Pt are Cu-enriched, with Cu:I ratios of ˜1:0.75. An XPS depth profile of CuI grown on Pt indicates that the copper concentration is greater closer to the CuI/Pt interface (FIG. 5(b)).

### Example 3

### Deposition of CuI on MAPbI₃

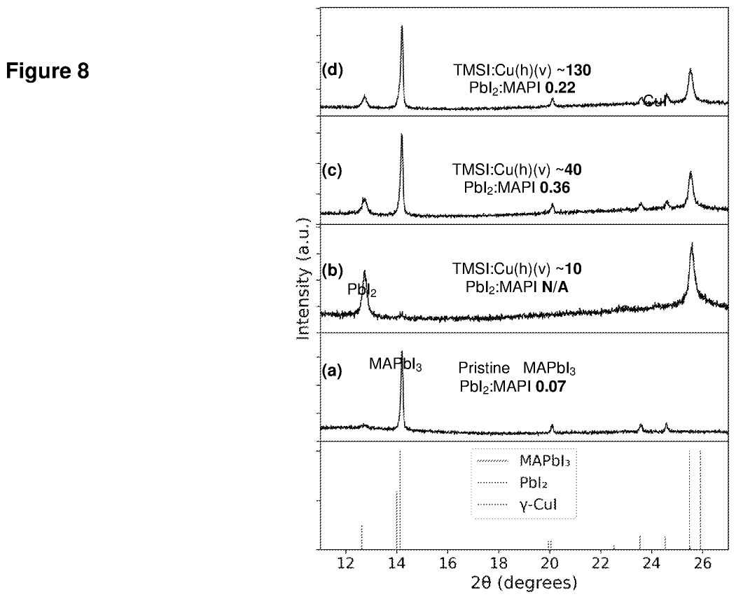

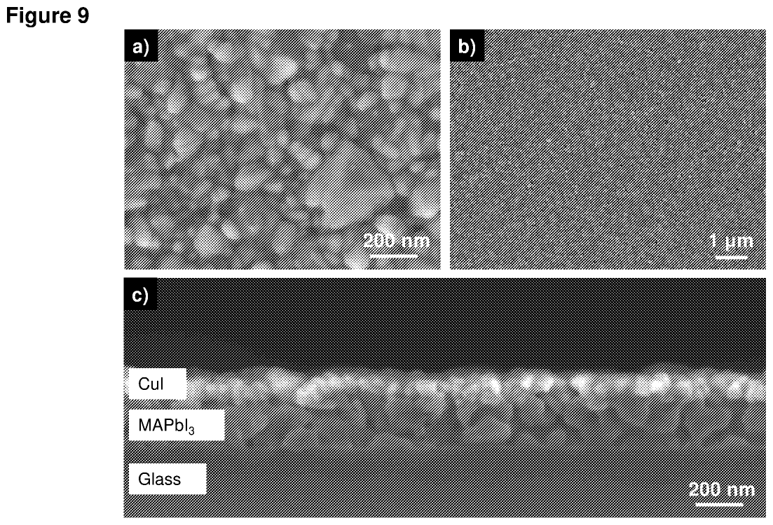

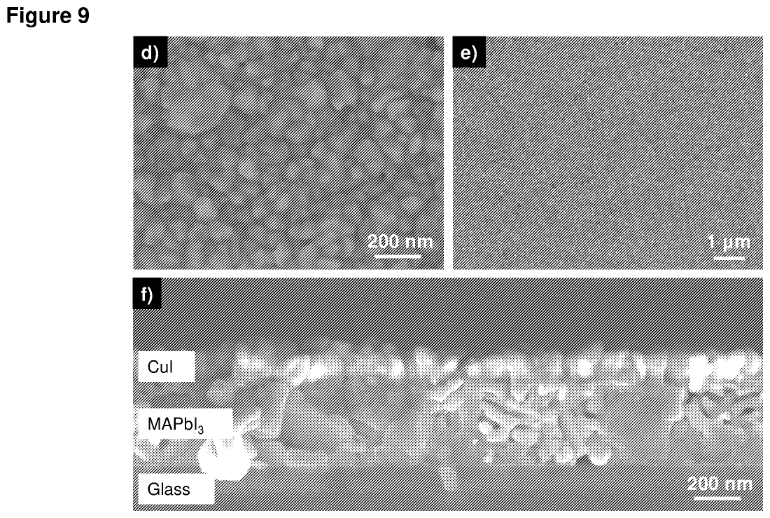

We have also demonstrated use of the techniques described herein to deposit CuI atop the perovskite absorber material methylammonium lead trisiodide (MAPbI₃). Perovskites films were prepared according to methods known in the art (see, Halford et al., ACS Appl. Mater. Interfaces 2022, 14, 4335-4343) After subjecting MAPbI₃ substrates to CuI deposition according to the methods described herein, the degree of MAPbI₃ degradation yielding PbI₂ was evaluated by XRD (FIG. 8). The relative amount of degradation is reported here as the area ratios of the PbI₂(001) to MAPbI₃(002/1̅1̅) XRD peaks; while these values can be used only to compare between samples, they do not provide absolute quantification of the MAPbI₃ and PbI₂ present within an individual sample. The as-received MAPbI₃ samples have area ratios <0.1. After 500 cycles of a pulsed CVD recipe optimized for deposition atop SiO₂ substrates, the MAPbI₃ peak was entirely absent. By increasing the estimated pressure ratio of TMSI to Cu(hfac)(vtms) during deposition from ˜10 to ˜40, the MAPbI₃ was better preserved, yielding an XRD peak area ratio of ˜0.4. Further increasing the TMSI to Cu(hfac)(vtms) ratio to ˜130 reduced the XRD peak area ratio to ˜0.2; scanning electron micrographs of these samples are shown in FIG. 9. Based on these results, further tuning of the deposition parameters including further increasing the TMSI to Cu(hfac)(vtms) ratio is expected to enable deposition of CuI atop MAPbI₃ with no MAPbI₃ degradation detectable by XRD. It is worth noting, too, that while MAPbI₃ is particularly delicate, the best-performing perovskite PVs typically utilize mixtures of this delicate material with its more robust close relatives containing cesium (CsPbI₃) and formamidinium (FAPbI₃) in place of methylammonium. Given the ability to control the degree of MAPbI₃ degradation during CuI CVD according to the methods described herein, with simple process modifications, deposition atop more robust perovskite absorber compositions more likely to be utilized in commercial perovskite solar cells will be feasible with even less damage to the absorber.

Additional experiments were performed with the individual precursors, where the perovskite was exposed to 500 pulses of a single precursor so that it was exposed to as much of that precursor as it would encounter during a 500 cycle open valve p-CVD deposition. When the perovskite was only exposed to TMSI, there was no MAPbI₃ decomposition detectable by XRD. When the perovskite was only exposed to Cu(hfac)(vtms), the perovskite was completely converted to PbI₁.

### Example 4

### ALD of Copper Halides

Atomic layer deposition of CuI was attempted with Cu(hfac)(vtms) and TMSI on NaCl(100). The deposition was run in closed valve mode. In one cycle of closed valve ALD, the reactor chamber is evacuated to base pressure, then the vacuum valve (1) is closed, and the first precursor is dosed into the reactor chamber. There is an incubation time where the precursor is held in the chamber, then the chamber is purged with nitrogen, evacuated back to base pressure, and the second precursor is dosed into the chamber using the same sequence: vacuum valve closed, precursor dosed in, incubation period, followed by purge and evacuation. The time sequence of a single cycle of closed valve ALD is described as t₁-t₂-t₃-t₄-t₅-t₆-t₇-t₈, where t₁ is the duration of the first precursor delivery pulse, t₂ is the incubation time where the first precursor is held in the reactor chamber, t₃ is the purge time, t₄ is the time to evacuate the chamber back to base pressure, t₅ is the second precursor dose, t₆ is the second precursor's incubation time, t₇ is the purge time, and t₈ is the evacuation time back to base pressure before the next cycle begins.

In a 500 cycle closed valve ALD deposition using timing sequence 0.5-1-10-90-0.5-1-10-90 with a substrate temperature of 50° C., a film was deposited on NaCl(100) (FIG. 15).

Scanning electron micrographs of the film deposited on NaCl(100) are shown in FIG. 15. XRD is consistent with deposition of a zincblende CuI film, with 111, 200, and 222 reflections observed (FIG. 16). Scanning electron micrographs of a cross section indicate film thicknesses of about 100 nm, corresponding to a growth rate of about 2 Å/cycle.

### OTHER EMBODIMENTS

While the invention has been described in connection with specific embodiments thereof, it will be understood that it is capable of further modifications and this application is intended to cover any variations, uses, or adaptations of the invention following, in general, the principles of the invention and including such departures from the invention that come within known or customary practice within the art to which the invention pertains and may be applied to the essential features hereinbefore set forth, and follows in the scope of the claims. Other embodiments are within the claims.

What is claimed is:

1. A method of producing a layer of a copper(I) halide, comprising:
a) providing a substrate; and
b) exposing the substrate to a vapor of halosilane and a vapor of a copper complex,
wherein the copper complex and halosilane react to produce a layer of copper(I) halide on the substrate.

2. The method of claim 1, wherein the halosilane is a trialkylhalosilane.

3. The method of claim 1, wherein the halosilane is Me₃Sil.

4. The method of claim 1, wherein the copper(I) halide is cuprous iodide. The method of claim 1, wherein the copper complex comprises an acetonato ligand.

6. The method of claim 1, wherein the copper complex comprises a vinyltrimethylsilane ligand.

7. The method of claim 1, wherein the copper complex is Cu(hfac)(L), wherein L is a neutral ligand.

8. The method of claim 7, wherein L is a phosphine, an alkene, an aromatic compound, or an alkyne.

9. The method of claim 7, wherein L is 2-butyne, bis(trimethylsilyl)acetylene, 2-methyl-1-hexen-3-yne or hex-3-yn-1-ene.

10. The method of claim 1, wherein the copper complex is Cu(hfac)(vtms) (vinyltrimethylsilane (hexafluoroacetylacetonato) copper(I)).

11. The method of claim 1, wherein the copper complex is Cu(hfac)(vtms) and the halosilane is Me₃Sil.

12. The method of claim 1, wherein the substrate is a current collector of a solar cell or a photovoltaic medium of a solar cell.

13. The method of claim 12, wherein solar cell is a perovskite solar cell.

14. The method of claim 13, wherein the perovskite comprises methylammonium tin trishalide, methylammonium lead trishalide, cesium tin trishalide, cesium lead trishalide, formamidinium tin trishalide, formamidinium lead trishalide, or a combination thereof.

15. The method of claim 1, wherein the substrate is SiO₂, SiNₓ, Pt, ITO, FTO, carbon, a flexible polymer film, a perovskite film, or single crystals of NaCl, KCl, or KBr.

16. The method of claim 1, wherein the substrate is a metal, a semiconductor, an optoelectronic material, a photovoltaic material, a dielectric, an interfacial layer, a sacrificial layer, a templating layer, or an adhesion layer.

17. The method of claim 1, wherein the substrate is first exposed to the halosilane vapor.

18. The method of claim 1, wherein a partial pressure of the halosilane vapor is from 10 to 500 times that of a copper complex vapor.

19. The method of claim 1, wherein a concentration of the halosilane vapor is from 10 to 500 times that of a copper complex vapor.

20. The method of claim 1, wherein step (b) comprises exposing the substrate to the halosilane and the copper complex at the same time or in a pulsed manner without purging between exposures followed by purging unreacted copper complex and halosilane to perform a cycle.

21. The method of claim 1, wherein step (b) comprises alternating exposure of the substrate to the halosilane and the copper complex separated by a purge to perform a cycle.

22. The method of claim 20, further comprising performing a plurality of cycles.

23. The method of claim 22, wherein the plurality of cycles comprises 10-50,000 cycles.

24. A solar cell comprising;
a) an electron injection layer;
c) an electron collection layer;
a) a perovskite absorbing layer disposed between the electron injection layer and electron collection layer;
b) an n-type electron transport layer disposed between the electron collection layer and the perovskite absorbing layer and the electron collecting layer; and
e) a p-type hole transport layer disposed between the perovskite absorbing layer;
wherein p-type hole transport layer comprises a copper halide; wherein the perovskite absorbing layer and the p-type hole transport layer are in physical contact.

25. The solar cell of claim 24, wherein the copper halide is copper iodide.

26. The solar cell of claim 24, wherein the perovskite absorbing layer has a ratio of XRD peak areas of MX₂ to QMX₃ of less than 22%, wherein Q is an ammonium counterion, X is a halide or a combination of halides, and M is a metal or combination of metals.

27. The solar cell of claim 26, wherein the ratio of MX₂ to QMX₃ is less than 10%.

28. The solar cell of claim 26, wherein the ratio of MX₂ to QMX₃ is less than 5%.

29. The solar cell of claim 26, wherein the ratio of MX₂ to QMX₃ is less than 1%.

30. The solar cell of claim 26, wherein M=Pb and X=I.

31. The solar cell of claim 26, wherein Q is methylammonium.

32. The solar cell of claim 24, wherein the perovskite absorber layer has a ratio of XRD peak areas of a degradation product to a peak of the perovskite that corresponds to less than 22% degradation by XRD.

33. The solar cell of claim 32, wherein the perovskite absorber layer shows less than 10% degradation by XRD.

34. The solar cell of claim 24, wherein the electron injection layer is reflective.

35. The solar cell of claim 24, wherein the electron injection layer is transparent or semi-transparent.

36. The solar cell of claim 24, wherein the electron collection layer comprises one or more of ITO, FTO, doped zinc oxide, In or Sn-doped cadmium oxide, Zn₂SnO₄, ZnSnO₃, Zn₂In₂O₅, Zn₃In₂O₆, Cd₂SnO₄, CdSnO₃, CdIn₂O₄, MgIn₂O₄, GaInO₃, Sn or Ge-doped gallium oxide, Y-doped CdSb₂O₆, Zn₂In₂O₅—In₄Sn₃O₁₂, CdIn₂O₄—Cd₂SnO₄, or ZnO—CdO—In₂O₃—SnO₂.

37. The solar cell of claim 24, wherein the perovskite has a structure of (Q′ₐQ″_{b}Q″′_{c})M═_{d}M″ₑ(X′_{f}X″_{g}X″′ₕ)₃, where a=0 to 1, b=0 to 1, c=0 to 1 and (a+b+c)=1, where d=0 to 1, e=0 to 1, and (d+e)=1, and wherein f=0 to 1, g=0 to 1, h=0 to 1 and (f+g+h)=1.

38. The solar cell of claim 24, wherein the perovskite comprises methylammonium tin trishalide, methylammonium lead trishalide, cesium tin trishalide, cesium lead trishalide, formamidinium tin trishalide, formamidinium lead trishalide, or a combination thereof.

39. The solar cell of claim 24, wherein the perovskite absorbing layer comprises MAPbBr₃, MAPbI₃, FAPbI₃, MAPb₁₋ₓSnₓI₃, or MASnI₃,

40. The solar cell of claim 24, wherein the p-type hole transport layer is deposited on the perovskite absorbing layer by chemical vapor deposition.

41. The solar cell of claim 24, wherein the p-type hole transport layer is a continuous layer of the copper halide.

42. A composition comprising:
a) a substrate; and
b) a copper halide layer in physical contact with the substrate;
wherein the substrate material physically or chemically degrades at temperatures between 35° C. and 200° C. and/or is chemically reactive to hydrogen halides and/or copper complexes at or above room temperature.

43. The composition of claim 42, wherein the copper halide layer is a CuI layer.

44. The composition of claim 42, wherein the substrate is a metal, a semiconductor, an optoelectronic material, a photovoltaic material, a dielectric, an interfacial layer, a sacrificial layer, a templating layer, or an adhesion layer.

45. The composition of claim 42, wherein the substrate comprises carbon, flexible polymer films, perovskite films, ITO-on-polymer, NaCl, KCl, or KBr.

46. The composition of claim 42, wherein the substrate is a photovoltaic material.

47. The composition of claim 42, wherein the substrate is a perovskite absorber layer.

48. The composition of claim 42, wherein the substrate has a ratio of XRD peak areas of a degradation product to a peak of the substrate that corresponds to less than 22% degradation by XRD.

49. The composition of claim 48, wherein the substate shows less than 10% degradation by XRD.

50. The composition of claim 42, further comprising one or more layers comprising one or more of ITO, FTO, doped zinc oxide, In or Sn-doped cadmium oxide, Zn₂SnO₄, ZnSnO₃, Zn₂In₂O₅, Zn₃In₂O₆, Cd₂SnO₄, CdSnO₃, CdIn₂O₄, MgIn₂O₄, GaInO₃, Sn or Ge-doped gallium oxide, Y-doped CdSb₂O₆, Zn₂In₂O₅—In₄Sn₃O₁₂, CdIn₂O₄—Cd₂SnO₄, or ZnO—CdO—In₂O₃—SnO₂.

51. The composition of claim 42, wherein the substrate comprises methylammonium tin trishalide, methylammonium lead trishalide, cesium tin trishalide, cesium lead trishalide, formamidinium tin trishalide, formamidinium lead trishalide, or a combination thereof.

52. The composition of claim 42, wherein the substrate comprises MAPbBr₃, MAPbI₃, FAPbI₃, MAPb₁₋ₓSnₓI₃, or MASnI₃,

53. The composition of claim 42, wherein the copper halide layer is deposited on the substrate by chemical vapor deposition.

54. The composition of claim 42, wherein the copper halide layer is a continuous film.
